(19) United States
(12) Patent Application Publication
(10) Pub. No.: US 2023/0006103 A1
(43) Pub. Date: Jan. 5, 2023

(54) DISPLAY DEVICE AND VIDEO WALL DISPLAY SYSTEM INCLUDING SAME

(71) Applicant: SAMSUNG DISPLAY CO., LTD., Yongin-si, Gyeonggi-do (KR)

(72) Inventors: Jin Oh KWAG, Yongin-si, Gyeonggi-do (KR); Seung Lyong BOK, Yongin-si, Gyeonggi-do (KR)

(73) Assignee: SAMSUNG DISPLAY CO., LTD., Yongin-si, Gyeonggi-do (KR)

(21) Appl. No.: 17/784,455

(22) PCT Filed: Nov. 13, 2020
(86) PCT No.: PCT/KR2020/016018

§ 371 Date: Jun. 10, 2022

(30) Foreign Application Priority Data
Dec. 11, 2019 (KR) 10-2019-0165087

(51) Int. Cl. H01L 33/38; G09F 9/302; G06F 3/14; G09F 9/33; H01L 33/62; H01Q 1/24

(52) U.S. Cl. CPC H01L 33/382; G09F 9/3026; G06F 3/1446; G09F 9/33; H01L 33/62; H01Q 1/243

(57) ABSTRACT

A display device includes a pixel circuit layer including a plurality of transistors, a first electrode and a second electrode disposed on a same layer on the pixel circuit layer, a light emitting element disposed between the first electrode and the second electrode, and an antenna pattern disposed on the light emitting element.

### CROSS-REFERENCE TO RELATED APPLICATION(S)

This application is a national entry of International Application No. PCT/KR2020/016018, filed on Nov. 13, 2020, which claims under 35 U.S.C. §§ 119(a) and 365(b) priority to and benefits of Korean Patent Application No. 10-2019-0165087, filed on Dec. 11, 2019, in the Korean Intellectual Property Office (KIPO), the entire contents of which are incorporated herein by reference.

### BACKGROUND

### 1. Technical Field

The disclosure relates to a display device and a video wall display system including the same.

### 2. Description of the Related Art

The display devices have grown in popularity and commercialization because of the interest in information display and the demand for portable information media.

### SUMMARY

Embodiments provide a video wall display system including multiple display devices connected with a wireless network through an antenna pattern.

Embodiments also provide a video wall display system in which each of the display devices includes a light emitting element of a nanometer scale to a micrometer scale.

Embodiments also provide a video wall display system in which each of the display devices includes a wireless power transfer antenna for wireless charging.

The objects of the disclosure are not limited to the object described above, and other technical objects which are not described will be clearly understood by those skilled in the art from the following description.

According to an embodiment of the disclosure for solving the above-described object, a display device includes a pixel circuit layer including a plurality of transistors, a first electrode and a second electrode disposed on a same layer on the pixel circuit layer, a light emitting element disposed between the first electrode and the second electrode, and an antenna pattern disposed on the light emitting element.

The display device may further include a first contact electrode electrically connecting an end of the light emitting element and the first electrode.

The antenna pattern and the first contact electrode may be disposed on a same layer.

The antenna pattern and the first contact electrode may be electrically separated from each other.

The display device may further include a second contact electrode electrically connecting another end of the light emitting element and the second electrode.

The first contact electrode may be disposed on the second contact electrode.

The display device may further include an insulating layer disposed between the antenna pattern and the second contact electrode, and the antenna pattern may overlap the second contact electrode in a plan view.

The display device may further include a first bridge pattern, and the first bridge pattern and the second contact electrode may be disposed on a same layer. The antenna pattern may be electrically connected to the first bridge pattern through a first contact hole formed in the insulating layer.

The first contact electrode, the second contact electrode, and the antenna pattern may be disposed on a same layer, and may be electrically separated from each other.

The display device may further include a touch electrode pattern, and the touch electrode pattern and the antenna pattern may be disposed on a same layer.

The display device may further include a first contact electrode, and the first contact electrode, the antenna pattern, and the touch electrode pattern may be disposed on a same layer. The first contact electrode may electrically connect an end of the light emitting element and the first electrode.

A transmit/receive frequency of the antenna pattern may be in a range of about 28 GHz to about 39 GHz.

The antenna pattern may include a transparent conductive material.

The display device may further include a first contact electrode electrically connecting an end of the light emitting element and the first electrode, and a second contact electrode electrically connecting another end of the light emitting element and the second electrode. The first contact electrode may be disposed on the second contact electrode, and the antenna pattern may be disposed under the second contact electrode.

The display device may further include a first contact electrode electrically connecting an end of the light emitting element and the first electrode, and a second contact electrode electrically connecting another end of the light emitting element and the second electrode. The antenna pattern may be disposed on the first contact electrode and the second contact electrode.

The display device may further include an encapsulation layer disposed on the first contact electrode and the second contact electrode, the antenna pattern may be disposed on the encapsulation layer, and the encapsulation layer may include at least one inorganic layer and an organic layer.

According to another embodiment of the disclosure for solving the above-described object, a video wall display system includes a plurality of display devices, each of the plurality of display devices including a display substrate, and an antenna pattern disposed on the display substrate. The display substrate includes a pixel circuit layer including a plurality of transistors, a first electrode and a second electrode formed on a same layer on the pixel circuit layer, and a light emitting element disposed between the first electrode and the second electrode.

The plurality of display devices may be electrically connected to each other through a wireless network.

The display substrate may include a bent area.

The display substrate of the video wall display system may further include a wireless power transfer antenna disposed under the display substrate.

The display substrate of the video wall display system may further include a speaker module disposed under the display substrate.

The speaker module may include a first speaker electrode, a second speaker electrode, and a vibration layer disposed between the first speaker electrode and the second speaker electrode.

The vibration layer may include at least one of poly vinylidene fluoride (PVDF), lead zirconate titanate ceramic (PZT), and electro active polymer.

According to still another embodiment of the disclosure for solving the above-described object, a video wall display system includes a plurality of display devices, each of the plurality of display devices including a display substrate including a plurality of transistors, and a plurality of light emitting elements, an antenna pattern disposed on the display substrate, and a network communication part transmitting and receiving a wireless signal to and from other display devices in the video wall display system through the antenna pattern.

Each of the plurality of light emitting elements may have a diameter and a length ranging from several hundred nanometer scale to several micrometer scale.

The video wall display system may further include a control part electrically connected to at least one of the plurality of display devices through a wireless network, and the control part may receive a user's instruction.

The details of other embodiments are included in the detailed description and drawings.

According to embodiments of the disclosure, a plurality of display devices in a video wall display system may be connected through a wireless network, and a delay time between display devices may be minimized.

Power may be wirelessly supplied to the video wall display system without a separate code.

Durability and efficiency of the video wall display system may be improved.

An effect according to embodiments is not limited by the contents exemplified above, and more various effects are included in the specification.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view of a video wall display system according to an embodiment of the disclosure;

FIG. 2 is a schematic control block diagram of a first display device according to an embodiment of the disclosure;

FIGS. 3 and 4 are a schematic perspective view and a schematic cross-sectional view illustrating a light emitting element according to an embodiment of the disclosure;

FIGS. 5 and 6 are a schematic perspective view and a schematic cross-sectional view illustrating a light emitting element according to another embodiment of the disclosure;

FIGS. 7 and 8 are a schematic perspective view and a schematic cross-sectional view illustrating a light emitting element according to still another embodiment of the disclosure;

FIG. 9 is a schematic plan view illustrating a first display device according to an embodiment of the disclosure;

FIG. 10 is a schematic cross-sectional view of the first display device corresponding to line of FIG. 9;

FIG. 11 is a schematic diagram of an equivalent circuit illustrating an example of a sub-pixel included in the first display device of FIG. 9;

FIGS. 12 to 18 are schematic diagrams of equivalent circuits illustrating an example that may be applied to a unit pixel included in the sub-pixel of FIG. 11;

FIG. 19 is a plan layout diagram schematically illustrating a disposition of a sub-pixel included in the first display device of FIG. 9;

FIG. 20 is a plan layout diagram schematically illustrating a disposition of another sub-pixel included in the first display device of FIG. 9;

FIG. 21 is a schematic cross-sectional view of a display substrate to an encapsulation layer corresponding to line I2-I2′ of FIG. 19 in the first display device;

FIG. 22 is a schematic cross-sectional view of the display substrate to the encapsulation layer corresponding to line I3-I3′ of FIG. 20 in the first display device;

FIG. 23 is a conceptual diagram illustrating a driving signal of each display device of a video wall display system according to an embodiment of the disclosure;

FIG. 24 is a schematic perspective view of a video wall display system according to another embodiment of the disclosure;

FIGS. 25 and 26 are schematic cross-sectional views of a display substrate to an encapsulation layer of a first display device of a video wall display system according to still another embodiment of the disclosure;

FIG. 27 is a schematic plan layout diagram schematically illustrating a disposition of a sub-pixel included in a first display device of a video wall display system according to still another embodiment of the disclosure;

FIG. 28 is a schematic cross-sectional view of the display substrate to the encapsulation layer corresponding to line II2-II2′ of FIG. 27 in the first display device;

FIG. 29 is a plan layout diagram schematically illustrating a disposition of a sub-pixel included in a first display device of a video wall display system according to still another embodiment of the disclosure;

FIG. 30 is a schematic cross-sectional view of the display substrate to the encapsulation layer corresponding to line III2-III2′ of FIG. 29 in the first display device;

FIG. 31 is a plan layout diagram schematically illustrating a disposition of a sub-pixel included in a first display device of a video wall display system according to still another embodiment of the disclosure;

FIG. 32 is a schematic cross-sectional view of a display substrate to an encapsulation layer in a first display device of a video wall display system according to still another embodiment of the disclosure;

FIG. 33 is a modified example of FIG. 32;

FIG. 34 is a plan layout diagram schematically illustrating a disposition of a sub-pixel included in a first display device of a video wall display system according to still another embodiment of the disclosure;

FIG. 35 is a schematic cross-sectional view of the display substrate to the encapsulation layer corresponding to line IV2-IV2′ of FIG. 34 in the first display device;

FIG. 36 is a modified example of FIG. 34;

FIG. 37 is a plan layout diagram schematically illustrating a disposition of a sub-pixel included in a first display device of a video wall display system according to still another embodiment of the disclosure;

FIG. 38 is a schematic cross-sectional view of the display substrate to the encapsulation layer corresponding to line V-V′ of FIG. 37 in the first display device;

FIG. 39 is a schematic perspective view of a first display device of a video wall display system according to still another embodiment of the disclosure;

FIG. 40 is a schematic cross-sectional view of the first display device shown in FIG. 39.

FIG. 41 is a schematic enlarged view of area AA of FIG. 40; and

FIG. 42 is a modified example of FIG. 1.

### DETAILED DESCRIPTION OF THE EMBODIMENTS

The advantages and features of the present disclosure and a method of achieving them will become apparent with reference to the embodiments described in detail below together with the accompanying drawings. However, the present disclosure is not limited to the embodiments disclosed below, and may be implemented in various different forms. The present embodiments are provided so that the disclosure will be thorough and complete and those skilled in the art to which the disclosure pertains can fully understand the scope of the present disclosure. The present disclosure is only defined by the scope of the claims.

A case in which an element or a layer is referred to as “on” another element or layer includes a case in which another layer or another element is disposed directly on the other element or between the other layers. The same reference numerals denote to the same components.

Although a first, a second, and the like are used to describe various components, these components are not limited by these terms. These terms are used only to distinguish one component from another component. Therefore, a first component mentioned below may be a second component within the technical spirit of the disclosure. Singular expressions may include plural expressions (or meanings) unless the context clearly indicates otherwise.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the present disclosure will be described in detail with reference to the accompanying drawings. The same or similar reference numerals are used for the same components in the drawings.

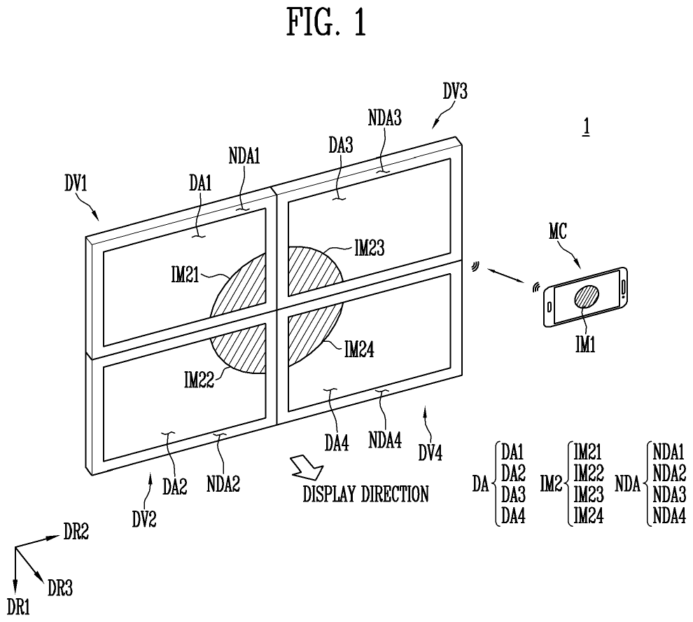

FIG. 1 is a schematic perspective view of a video wall display system according to an embodiment of the disclosure.

Referring to FIG. 1, as an embodiment, a video wall display system 1 may include display devices DV1 to DV4 arranged in an order and a control unit (or control part) MC connected to the display devices DV1 to DV4 through a wireless network. Each of the display devices DV1 to DV4 may receive a signal from the control unit MC and/or adjacent display devices DV1 to DV4 through an antenna pattern provided inside the display devices DV1 to DV4, and may transmit the signal to adjacent display devices DV1 to DV4 again. For example, in case that at least one display device among the display devices DV1 to DV4 receives an image signal, the at least one display device may transfer an image signal to all display devices DV1 to DV4 in a method of bypassing the image signal. Although a position of each of the display devices DV1 to DV4 is not determined, the display devices DV1 to DV4 may be arranged in a matrix form. FIG. 1 is configured in a form of a 2×2 matrix (e.g., width×length matrix). At least one of the width and length may be increased or decreased. In the embodiment, the display devices DV1 to DV4 may include the first display device DV1 to the fourth display device DV4, and the second display device DV2 may be disposed on a lower side, the third display device DV3 may be disposed on a left side, and the fourth display device DV4 may be disposed on a lower left side based on the first display device DV1.

The control unit MC may function as a host system. For example, the control unit MC may be implemented as any one of a television system, a home theater system, a set-top box, a navigation system, a DVD player, a Blu-ray player, a personal computer (PC), a mobile phone system, and a tablet.

As an embodiment, a user's instruction (or command) may be input to the control unit MC in various formats. For example, the control unit MC may include a touch input part, and an instruction (or command) by a user's touch input (or touch event) may be input to the control unit MC. However, the disclosure is not limited thereto, and the user's instruction (or command) may be input to the control unit MC through various suitable methods such as an input method, a button input method, or the like through the remote control unit.

As an embodiment, the display devices DV1 to DV4 may be used as a large electronic device such as a television and a monitor, and a small and medium-sized electronic device such as a mobile phone, a tablet, a car navigation system, a game machine, and a smartwatch.

The video wall display system 1 may include a display area DA and a non-display area NDA. The display devices DV1 to DV4 may include display areas DA1 to DA4 and non-display areas NDA1 to NDA4, respectively.

Each of the display areas DA1 to DA4 may be defined as an area in which a corresponding image is displayed. The non-display areas NDA1 to NDA4 may be defined as areas in which an image is not displayed. Each of the non-display areas NDA1 to NDA4 may be adjacent to each of the display areas DA1 to DA4. The display areas DA1 to DA4 may have a quadrangle shape. The non-display areas NDA1 to NDA4 may have a shape surrounding the display areas DA1 to DA4. For example, the first display area DA1 may have a shape surrounded by the first non-display area NDA1, the second display area DA2 may have a shape surrounded by the second non-display area NDA2, the third display area DA3 may have a shape surrounded by the third non-display area NDA3, and the fourth display area DA4 may have a shape surrounded by the fourth non-display area NDA4. However, the disclosure is not limited thereto, and the shape of each of the display areas DA1 to DA4 and the shape of each of the non-display areas NDA1 to NDA4 may be relatively changed.

Each of the display areas DA1 to DA4 may be parallel to a plane defined by a first direction DR1 and a second direction DR2. A thickness direction of each of the display devices DV1 to DV4 may be defined as a normal direction of each of the display areas DA1 to DA4. For example, a third direction DR3 may indicate the thickness direction.

As an embodiment, an image in which images to be displayed on each of the display devices DV1 to DV4 are merged may be displayed on the control unit MC, but the disclosure is not limited thereto.

Each of the display devices DV1 to DV4 may display an image corresponding to a unique ID thereof. For example, the control unit MC may divide data corresponding to a first image IM1 to be displayed by the number of the display devices DV1 to DV4. The control device MC may transmit a portion to the first display device DV1, transmit another portion to the second display device DV2, transmit still another portion to the third display device DV3, and transmit further still another portion to the fourth display device DV4. The first display device DV1 may display a first sub-image IM21 corresponding to the transmitted data, the second display device DV2 may display a second sub-image IM22 corresponding to the transmitted data, the third display device DV3 may display a third sub-image IM23 corresponding to the transmitted data, and the fourth display device DV4 may display a fourth sub-image IM24 corresponding to the transmitted data.

The user may see each of the sub-images IM21 to IM24 displayed on the first to fourth display devices DV1 to DV4 and may recognize as a new second image IM2 in which the first to fourth sub-images IM21 to IM24 are merged. The second image IM2 may be recognized as an image having a shape substantially the same as that of the first image IM1 and having a size different from that of the first image IM1 to the user.

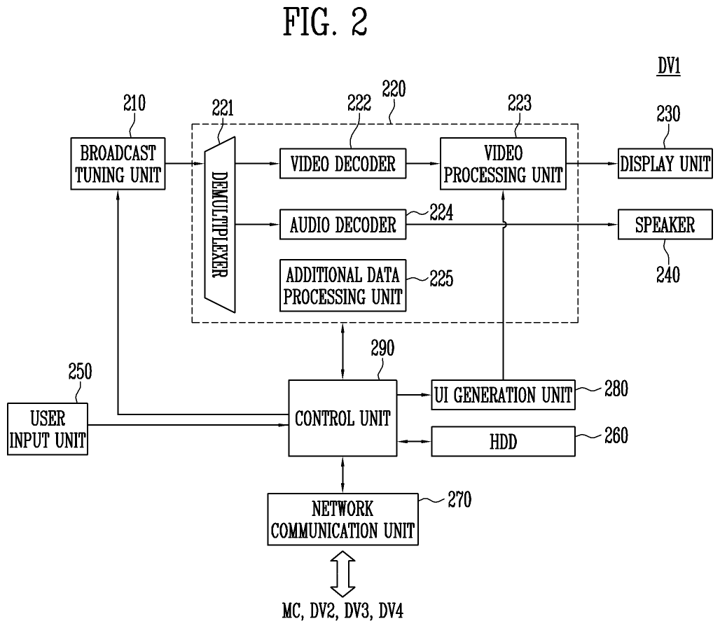

FIG. 2 is a schematic control block diagram of a first display device according to an embodiment of the disclosure. Since a description of the control block diagram of the first display device DV1 may be substantially identically applied to the second to fourth display devices DV2 to DV4, detailed description of the same elements is omitted.

Referring to FIG. 2, the first display device DV1 may include a broadcast tuning unit (or broadcast tuning part) 210, a signal processing unit (or signal processing part) 220, a display unit (or display part) 230, a speaker 240, a user input unit (or user input part) 250, an HDD 260, and a network communication unit (or network communication part) 270, a UI generation unit (or UI generation part) 280, and a control part 290.

The broadcast tuning part 210 may tune a channel frequency under control of a control part 290 and receive a broadcast signal of a corresponding channel through an antenna, and includes a channel detection module (not shown) and an RF demodulation module (not shown).

A broadcast signal demodulated by the broadcast tuning part 210 may be processed by the signal processing part 220 and output to the display part 230 and the speaker 240. The signal processing part 220 may include a demultiplexer 221, a video decoder 222, a video processing unit (or video processing part) 223, an audio decoder 224, and an additional data processing unit (or additional data processing part) 225.

The demultiplexer 221 may divide the demodulated broadcast signal into a video signal, an audio signal, and additional data. The divided video signal, the divided audio signal, and the divided additional data may be restored by the video decoder 222, the audio decoder 224, and the additional data processing part 225, respectively. The video decoder 222, the audio decoder 224, and the additional data processing part 225 may restore as a decoding format corresponding to an encoding format when the broadcast signal is transmitted.

The decoded video signal (or restored video signal) may be converted by the video processing part 223 to fit a vertical frequency, resolution, a screen ratio, and the like corresponding to an output standard of the display part 230, and a decoded audio signal may be output to the speaker 240.

The display part 230 may include a panel (not shown) provided with the first display area DA1 on which an image is displayed, and a panel driving unit (or panel driving part) (not shown) controlling driving (or operation) of the panel.

The user input part 250 may receive a signal transmitted from the control unit MC. The user input part 250 may be provided to allow the user to receive an instruction (or command) related to communication with other display devices DV2 to DV4 and input data for an input as well as data related to selection of a channel, selection of a user interface (UI) menu, and manipulation transmitted by the control unit MC.

The HDD 260 may store various software programs including an OS program, a recorded broadcast program, a moving picture, a photo, or other data, and may be implemented by another storage media.

The network communication part 270 may be for short-range communication with the control unit MC and other display devices DV2 to DV4. The network communication part 270 may be implemented with a communication module including an antenna pattern that may implement mobile communication, data communication, Bluetooth, RF, Ethernet, or the like.

The network communication part 270 may transmit and receive wireless signal with at least one of a base station, an external terminal, and a server on a mobile communication network built according to technical standards or a communication method (e.g., global system for mobile communication (GSM), code division multi access (CDMA), code division multi access (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), 5G, or the like. Description of the network communication 270 is provided below.

The network communication part 270 may transmit and receive a wireless signal in a communication network according to wireless Internet technologies through the antenna pattern. The wireless Internet technologies may include, for example, wireless LAN (WLAN), wireless-fidelity (Wi-Fi), wireless fidelity (Wi-Fi) direct, digital living network alliance (DLNA), wireless broadband access service (WiBro), world interoperability for microwave access (WiMAX), high speed downlink packet access (HSDPA), high speed uplink packet access (HSUPA), long term evolution (LTE), long term evolution-advanced (LTE-A), or the like. The antenna pattern may transmit and receive data according to at least one wireless Internet technology within a range including an Internet technology which is not listed above.

The UI generation part 280 may generate a UI menu for communication with the control unit MC and another display devices DV2 to DV4. The UI generation part 280 may be implemented by an algorithm code and an OSD IC. The UI menu, by which the display device DV1 communicate with the control unit MC and another display devices DV2 to DV4, may be a menu for designating a counterpart digital TV and selecting a desired function. The UI menu according to an embodiment of the disclosure may include, “power on/off”, “channel switching”, “recent channel”, “send channel”, “quality setting”, “audio setting”, “data transmission”, “data update”, or the like, but is not limited thereto.

The control unit 290 may be in charge of overall control of the first display device DV1 and be in charge of communication control of the control unit MC and another display devices DV2 to DV4. A corresponding algorithm code for control may be stored in the control part 290, and the control unit 290 may be implemented by a micro controller unit (or micro controller part) (MCU) in which the stored algorithm code is executed. The control part 290 may transmit channel information and other data currently being viewed with another digital TV within a communicable network. Each digital TV may transmit and receive various data regardless of power on/off state. Each digital TV may transmit a power-off state instead of channel information in a case of the power-off state.

The control part 290 may control to transmit a corresponding control instruction and data to the control part MC and other display devices DV2 to DV4 through the network communication part 270 according to an input and selection of the user input part 250. In case that a control instruction (or command) and data are input from the control unit MC and other display devices DV2 to DV4, an operation may be performed according to the corresponding control instruction (or command).

Hereinafter, elements configuring each of the display devices DV1 to DV4 are described based on the first display device DV1. Since a description of the elements of the first display device DV1 may be substantially identically to those applied to the second to fourth display devices DV2 to DV4, detailed description of the same constituent elements is omitted.

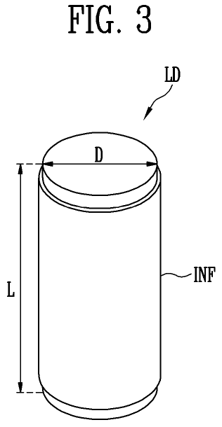

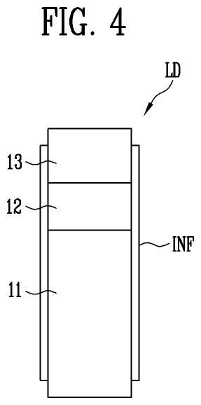

FIGS. 3 and 4 are a schematic perspective view and a schematic cross-sectional view illustrating a light emitting element according to an embodiment of the disclosure.

In FIGS. 3 and 4, a bar shape light emitting element LD having a circular columnar shape is shown, but a type and/or shape of the light emitting element LD according to the disclosure is not limited thereto.

Referring to FIGS. 3 and 4, the light emitting element LD may include a first conductive electrode layer 11, a second conductive electrode layer 13, and an active layer 12 interposed between the first and second conductive electrode layers 11 and 13. For example, the light emitting element LD may be configured as a stack in which the first conductive electrode layer 11, the active layer 12, and the second conductive electrode layer 13 are sequentially stacked in a direction.

According to an embodiment, the light emitting element LD may be provided in a bar shape extending in a direction. The light emitting element LD may have a side end and another side end along a direction.

According to an embodiment, one of the first and second conductive electrode layers 11 and 13 may be disposed at the side end of the light emitting element LD, and the remaining one of the first and second conductive electrode layers 11 and 13 may be disposed at another side end of the light emitting element LD.

According to an embodiment, the light emitting element LD may be a bar shape light emitting diode manufactured in a bar shape. The bar shape may encompass a rod-like shape or a bar-like shape that is longer in a longitudinal direction than in a width direction (e.g., having an aspect ratio greater than 1), such as a circular column or a polygonal column, and a shape of a cross section thereof is not limited thereto. For example, a length L of the light emitting element LD may be greater than a diameter D (or a width of the cross section) thereof.

According to an embodiment, the light emitting element LD may have the diameter D and/or the length L as small as a nanometer scale to a micrometer scale, for example, a range of several hundred nanometer scale to several micrometer scale. However, a size of the light emitting element LD is not limited thereto. For example, the size of the light emitting element LD may be variously changed according to a design condition of various devices using a light emitting device using the light emitting element LD as a light emitting unit (or light emitting part), for example, the display devices DV1 to DV4.

The first conductive electrode layer 11 may include at least one n-type semiconductor material. For example, the first conductive electrode layer 11 may include at least one semiconductor material of InAlGaN, GaN, AlGaN, InGaN, AlN, and InN, and may include an n-type semiconductor layer doped with a first conductive dopant such as Si, Ge, or Sn. However, the material configuring the first conductive electrode layer 11 is not limited thereto, and various materials in addition to the above-described materials may configure the first conductive electrode layer 11.

The active layer 12 may be disposed on the first conductive electrode layer 11 and may be formed in a single or multiple quantum well structure. In an embodiment, a clad layer (not shown) doped with a conductive dopant may be formed on and/or under the active layer 12. For example, the clad layer may be formed of an AlGaN layer or an InAlGaN layer. According to an embodiment, a material of AlGaN, AlInGaN, or the like may be used to form the active layer 12, and various materials in addition to the above-described materials may configure the active layer 12.

In case that a voltage equal to or greater than a threshold voltage is applied to ends of the light emitting element LD, the light emitting element LD may emit light while an electron-hole pair is recombined in the active layer 12. Light emission of the light emitting element LD may be controlled by using such a principle (e.g., coupling of electron-hole pair), and the light emitting element LD may be used as a light emitting part of various light emitting devices including a pixel of the display devices DV1 to DV4.

The second conductive electrode layer 13 may be disposed on the active layer 12 and may include a semiconductor material of a type different from that of the first conductive electrode layer 11. For example, the second conductive electrode layer 13 may include at least one p-type semiconductor layer. For example, the second conductive electrode layer 13 may include at least one semiconductor material of InAlGaN, GaN, AlGaN, InGaN, AlN, and InN, and may include a p-type semiconductor material doped with a second conductive dopant such as Mg. However, the material configuring the second conductive electrode layer 13 is not limited thereto, and various materials in addition to the above-described materials may configure the second conductive electrode layer 13.

According to an embodiment, the light emitting element LD may further include an insulating film INF provided on a surface thereof. The insulating film INF may be formed on a surface of the light emitting element LD so as to surround at least an outer circumferential surface of the active layer 12. The insulating film INF may further surround an area of the first and second conductive electrode layers 11 and 13. However, the insulating film INF may expose both ends of the light emitting element LD having different polarities. For example, the insulating film INF may not cover and may expose an end of each of the first and second conductive electrode layers 11 and 13 positioned at ends of the light emitting element LD in a longitudinal direction, for example, two planes of a cylinder (that is, an upper surface and a lower surface).

According to an embodiment, the insulating film INF may include at least one insulating material of silicon dioxide (SiO₂), silicon nitride (Si₃N₄), aluminum oxide (Al₂O₃), and titanium dioxide (TiO₂), but is not limited thereto. For example, a configuration material of the insulating film INF is not particularly limited thereto, and the insulating film INF may be configured of various insulating materials.

In an embodiment, the light emitting element LD may further include an additional component in addition to the first conductive electrode layer 11, the active layer 12, the second conductive electrode layer 13, and/or the insulating film INF. For example, the light emitting element LD may further include at least one of a phosphor layer, an active layer, a semiconductor material, and an electrode layer disposed on an end side of the first conductive electrode layer 11, the active layer 12, and/or the second conductive electrode layer 13.

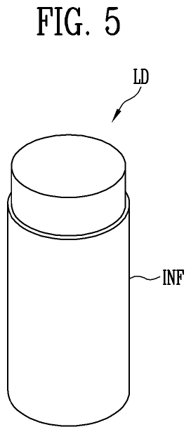

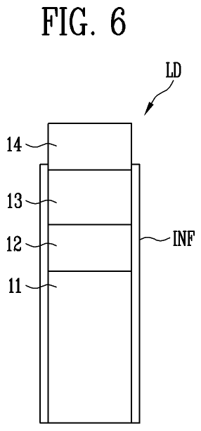

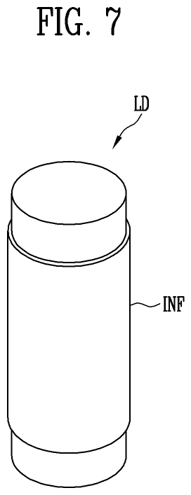

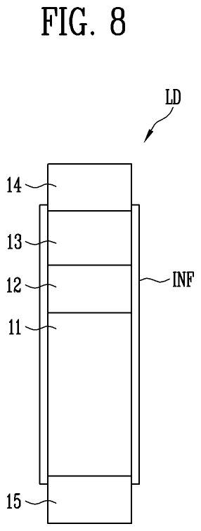

FIGS. 5 and 6 are a schematic perspective view and a schematic cross-sectional view illustrating a light emitting element according to another embodiment of the disclosure. FIGS. 7 and 8 are a schematic perspective view and a schematic cross-sectional view illustrating a light emitting element according to still another embodiment of the disclosure.

Referring to FIGS. 5 and 6, the light emitting element LD may further include at least one electrode layer 14 disposed on an end side of the second conductive electrode layer 13.

Referring to FIGS. 7 and 8, the light emitting element LD may further include at least another electrode layer 15 disposed on an end side of the first conductive electrode layer 11.

Each of the electrode layers 14 and 15 may be an ohmic contact electrode, but is not limited thereto. Each of the electrode layers 14 and 15 may include a metal or a conductive metal oxide, and for example, each of the electrode layers 14 and 15 may be formed of at least one of chromium (Cr), titanium (Ti), aluminum (Al), gold (Au), nickel (Ni), an oxide or an alloy thereof, a transparent electrode material such as indium tin oxide (ITO), indium zinc oxide (IZO), zinc oxide (ZnO), or an indium tin zinc oxide (ITZO) alone, or in combination thereof. The electrode layers 14 and 15 may be substantially transparent or translucent. Therefore, light generated in the light emitting element LD may pass through the electrode layers 14 and 15 and may be emitted to the outside of the light emitting element LD.

According to an embodiment, the insulating film INF may or may not at least partially surround outer circumferential surfaces of the electrode layers 14 and 15. For example, the insulating film INF may be selectively formed on surfaces of the electrode layers 14 and 15. The insulating film INF may be formed to expose ends of the light emitting elements LD having different polarities. For example, the insulating film INF may expose at least one area of the electrode layers 14 and 15. However, the disclosure is not limited thereto, and the insulating film INF may not be provided.

Since the insulating film INF is provided on a surface of the light emitting element LD, for example, a surface of the active layer 12, the active layer 12 may be prevented from being shorted with at least one electrode (e.g., at least one contact electrode of contact electrodes electrically connected to ends of the light emitting element LD). Accordingly, electrical stability of the light emitting element LD may be secured.

Since the insulating film INF is formed on the surface of the light emitting element LD, a surface defect of the light emitting element LD may be minimized, and lifespan and efficiency of the light emitting element LD may be improved. Since the insulating film INF is formed on the surface of the light emitting element LD, an unwanted short between the light emitting elements LD may be prevented although multiple light emitting elements LD are disposed in close.

In an embodiment, the light emitting element LD may be manufactured through a surface treatment process (e.g., coating). For example, in case that light emitting elements LD are mixed in a fluid solution (or solvent) and supplied to each emission area (e.g., an emission area of each pixel), the light emitting elements LD may be uniformly dispersed in the solution without being uniformly aggregated. The emission area may be an area where light is emitted by the light emitting elements LD, and may be distinguished from a non-emission area where light is not emitted.

According to embodiments, the insulating film INF itself may be formed as a hydrophobic film using a hydrophobic material, or a hydrophobic film formed of a hydrophobic material may be additionally formed on the insulating film INF. According to an embodiment, the hydrophobic material may be a material containing fluorine to exhibit hydrophobicity. According to an embodiment, the hydrophobic material may be applied to the light emitting elements LD in a form of a self-assembled monolayer (SAM). The hydrophobic material may include octadecyl trichlorosilane, fluoroalkyl trichlorosilane, perfluoroalkyl triethoxysilane, or the like. The hydrophobic material may be a commercially available fluorine-containing material such as Teflon™ or Cytop™, or a material corresponding thereto.

The light emitting device including the light emitting element LD may be used in various types of devices that require a light emitting part. The display devices DV1 to DV4 according to the embodiment may include the light emitting element LD as the light emitting part. For example, at least one ultra-small light emitting element LD (e.g., ultra-small light emitting elements LD each having size from a nanometer scale to a micrometer scale may be disposed in each pixel area of the display devices DV1 to DV4. The light emitting part of each pixel may be configured using the ultra-small light emitting element LD. However, an application field of the light emitting element LD is not limited to the display devices DV1 to DV4 in the disclosure. For example, the light emitting element LD may be used in other types of devices that require a light source, such as a lighting device.

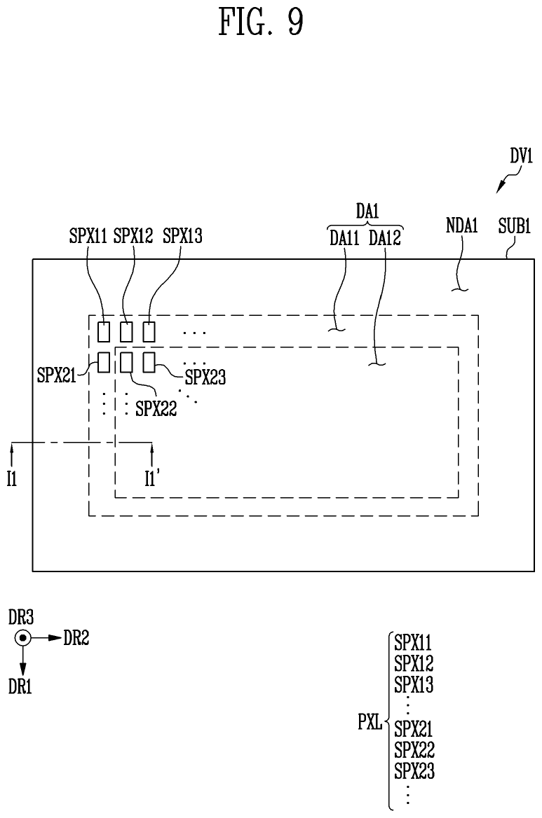

FIG. 9 is a schematic plan view illustrating a first display device according to an embodiment of the disclosure. According to an embodiment, FIG. 9 shows the first display device DV1 that may use the light emitting elements LD described in FIGS. 3 to 8 as the light emitting part.

The first display device DV1 may include a base layer SUB1 (or substrate) and pixels PXL disposed on the base layer SUB1. For example, as described above, the first display device DV1 and the base layer SUB1 may include a first display area DA1 in which an image is displayed and a first non-display area NDA1 excluding the first display area DA1. For example, the first display area DA1 and the first non-display area NDA1 may be defined in the base layer SUB1.

As an embodiment, the first display area DA1 may include a first sub-display area DA11 in which an antenna pattern is disposed and a second sub-display area DA12 in which an antenna pattern is not disposed. For example, a second sub-display area DA12 may include a touch electrode pattern for sensing a user's touch input (or touch event) and/or a piezoelectric sensor pattern for sensing a user's press. However, the disclosure is not limited thereto, and according to an embodiment, the first display area DA1 may be formed of only the first sub-display area DA11 in which the antenna pattern is disposed.

As an embodiment, the first sub-display area DA11 may be positioned at an edge of the first display area DA1, and the second sub-display area DA12 may be positioned inside the first sub-display area DA11.

The base layer SUB1 may configure a base member of the first display device DV1. For example, the base layer SUB1 may configure a base member of a lower panel (e.g., lower plate of the display device DV1).

According to an embodiment, the base layer SUB1 may be a rigid substrate or a flexible substrate, and a material or a physical property of the base layer SUB1 is not limited thereto. For example, the base layer SUB1 may be a rigid substrate configured of glass or tempered glass, or a flexible substrate configured of a thin film of a plastic or metallic material. The base layer SUB1 may be a transparent substrate, but is not limited thereto. For example, the base layer SUB1 may be a translucent substrate, an opaque substrate, or a reflective substrate. The embodiment describes that the base layer SUB1 is the flexible substrate as an example.

An area of the base layer SUB1 may be defined as the first display area DA1 and the pixels PXL, and a remaining area on the base layer SUB1 may be defined as the first non-display area NDA1. For example, the base layer SUB1 may include the first display area DA1 including emission areas in which the pixel PXL is formed, and the first non-display area NDA1 disposed outside the first display area DA1. Various lines and/or a built-in circuit electrically connected to the pixels PXL of the first display area DA1 may be disposed in the first non-display area NDA1.

The pixel PXL may include at least one light emitting element LD driven by corresponding scan signal and data signal, e.g., at least one bar shape light emitting diode according to any one of the embodiments of FIGS. 3 to 8. For example, the pixel PXL may include multiple bar shape light emitting diodes having a size as small as a nanometer scale to a micrometer scale and electrically connected in parallel to each other. The bar shape light emitting diodes may configure a light emitting part of the pixel PXL.

The pixel PXL may include multiple sub-pixels. For example, the pixel PXL may include a first sub-pixel SPX11, a second sub-pixel SPX12, a third sub-pixel SPX13, a fourth sub-pixel SPX21, a fifth sub-pixel SPX22, and a sixth sub-pixel SPX23. The sub-pixels may be disposed in a matrix form. For example, the first sub-pixel SPX11 may be disposed in a first row and a first column, the second sub-pixel SPX12 may be disposed in the first row and a second column, the third sub-pixel SPX13 may be disposed in the first row and a third column, the fourth sub-pixel SPX21 may be disposed in a second row and the first column, the fifth sub-pixel SPX22 may be disposed in the second row and the second column, and the sixth sub-pixel SPX23 may be disposed in the second row and the third column. A column direction may be indicated by a first direction DR1, and a row direction may be indicated by a second direction DR2.

As an embodiment, the first sub-pixel SPX11, the second sub-pixel SPX12, the third sub-pixel SPX13, and the fourth sub-pixel SPX21 may be positioned in the first sub-display area DA11. The fifth sub-pixel SPX22 and the sixth sub-pixel SPX23 may be positioned in the second sub-display area DA12. The antenna pattern may be disposed in the first sub-pixel SPX11, the second sub-pixel SPX12, the third sub-pixel SPX13, and the fourth sub-pixel SPX21 positioned in the first sub-display area DA11. An antenna pattern may not be disposed, and a touch electrode pattern and/or a piezoelectric sensor pattern may be disposed in the fifth sub-pixel SPX22 and the sixth sub-pixel SPX23 positioned in the second sub-display area DA12.

According to an embodiment, the first to sixth sub-pixels SPX11 to SPX23 may emit light in the same or different colors. For example, the first sub-pixel SPX11 and the fourth sub-pixel SPX21 may be red sub-pixels emitting red light, the second sub-pixel SPX12 and the fifth sub-pixel SPX22 may be green sub-pixels emitting green light, and the third sub-pixel SPX13 and the sixth sub-pixel SPX23 may be blue sub-pixels emitting blue light. However, the color, type, number, and/or the like of the sub-pixels configuring the pixel PXL are/is not particularly limited thereto, and for example, the color of light emitted by each of the sub-pixels may be variously changed. Although FIG. 9 shows an embodiment in which the pixels PXL are arranged in a matrix form in the first display area DA1, the disclosure is not limited thereto. For example, the pixels PXL may be disposed in various pixel arrangement shapes.

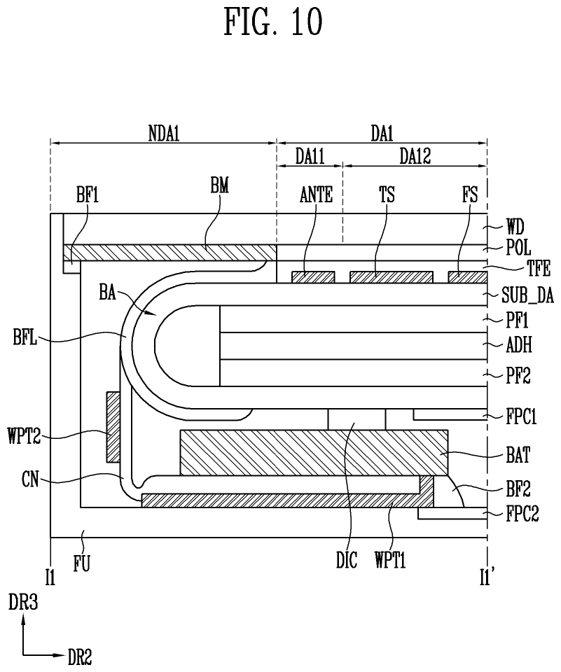

FIG. 10 is a schematic cross-sectional view of the first display device corresponding to line I1-I1′ of FIG. 9.

Referring to FIG. 10, a display substrate SUB_DA may be a flexible substrate and may be formed of a plastic material or a metal foil. For example, since the display substrate SUB_DA may be formed of a flexible material, the display substrate SUB_DA may be bent as shown.

For example, the display substrate SUB_DA of the plastic material may include at least one material of polyimide (PI), polycarbonate (PC), polynorborneen (PNB), polyethyleneterephthalate (PET), polyethylenapthanate (PEN), and polyethersulfone (PES). The first display area DA1 and the first non-display area NDA1 may be defined in the display substrate SUB_DA. The first display area DA may include the first sub-display area DA11 and the second sub-display area DA12.

Transistors and light emitting elements may be disposed in the first display area DA1 of the display substrate SUB_DA. A description of the transistors and light emitting elements is described below. At least a portion of the first non-display area NDA1 of the display substrate SUB_DA may be the bending area BA, and pads (not shown) may be disposed in the first non-display area NDA1 of the display substrate SUB_DA.

In the display substrate SUB_DA, two areas divided based on the bending area BA by a bending shape may face each other. The two areas may overlap each other in a plan view. In the specification, the expression “overlap” means that two configuration overlaps in a thickness direction (e.g., the third direction DR3 or in a plan view) of the first display device DV1 unless otherwise defined.

Accordingly, all of the antenna pattern ANTE, a touch electrode pattern TS, a piezoelectric sensor pattern FS, and a driving integrated circuit DIC may be disposed on the display substrate SUB_DA. However, the antenna pattern ANTE, the touch electrode pattern TS, and the piezoelectric sensor pattern FS may be positioned on the display substrate SUB_DA, and the driving integrated circuit DIC may be positioned under the display substrate SUB_DA based on a cross-section of the first display device DV1.

Although not clearly shown, the antenna pattern ANTE may be electrically connected to a corresponding feed wire through a contact hole. Accordingly, the antenna pattern ANTE may be electrically connected to an RF driving part disposed on a first flexible circuit board FPC1 or the like through the feed wire. Therefore, the antenna pattern ANTE may be used as a patch antenna for mobile communication or as an antenna for an RFID tag for short-range communication.

A cushion member ADH may be disposed between the bent display substrates SUB_DA. The cushion member ADH may be formed of various materials having a cushion. For example, the cushion member ADH may be formed of latex, sponge, urethane foam which is a foamable resin, EVA, silicone, or the like. The cushion member ADH may be formed in a tape shape having a cushion. The cushion member ADH may be an adhesive member.

A first protection film PF1 and a second protection film PF2 may be disposed between the cushion member ADH and the display substrate SUB_DA. For example, the first protection film PF1 may be disposed between the cushion member ADH and an area of the display substrate SUB_DA positioned in a relatively upper portion, and the second protection film PF2 may be disposed between the cushion member ADH and another area of the display substrate SUB_DA positioned in a relatively lower portion.

Each of the first protection film PF1 and the second protection film PF2 may be formed of plastic such as polyethylene terephthalate (PET), polyethylene naphthalate (PEN), polyimide (PI), and polyethersulfone (PES), but is not limited thereto. The first protection film PF1 and the second protection film PF2 may entirely cover a rear surface of the display substrate SUB_DA. However, in order to reduce bending stress of the bending area BA, they may not be disposed on a rear surface of a portion where the bending area BA is formed.

The antenna pattern ANTE, the touch electrode pattern TS, and/or the piezoelectric sensor pattern FS may be disposed in the first display area DA1 of the display substrate SUB_DA. As an embodiment, the antenna pattern ANTE, the touch electrode pattern TS, and/or the piezoelectric sensor pattern FS may be simultaneously formed by a same process.

An encapsulation layer TFE may be disposed on the antenna pattern ANTE, the touch electrode pattern TS, and/or the piezoelectric sensor pattern FS. The encapsulation layer TFE may be formed to cover the antenna pattern ANTE, the touch electrode pattern TS, and/or the piezoelectric sensor pattern FS, a transistor, and light emitting elements (e.g., light emitting elements LD shown in FIGS. 3 to 8) to protect them from external moisture or air.

A polarization layer POL may be disposed on the encapsulation layer TFE. The polarization layer POL may overlap the encapsulation layer TFE in a plan view.

The polarization layer POL may transmit light parallel to a polarization axis of a direction among light output from the light emitting element (e.g., light emitting element LD shown in FIGS. 3 to 8). The polarization layer POL may reduce external light reflection. The polarization layer POL may be a coating type polarization layer POL or a polarization layer POL formed by deposition. The polarization layer POL may be formed by coating a material including a dichroic dye and a liquid crystal compound on the encapsulation layer TFE.

A bending stress relief member BFL may be disposed on the bending area BA of the display substrate SUB_DA. The bending stress relief member BFL may reduce bending stress of a substrate (e.g., display substrate SUB_DA) generated in the bending area BA.

The bending stress relief member BFL may include an adhesive formed of a resin. Since the bending stress relief member BFL is cured in a state in which the bending stress relief member BFL is attached to an outer surface of the bending area BA, a shape of the bent substrate (e.g., display substrate SUB_DA) may be more stably maintained. The bending stress relief member BFL may be formed of a thermosetting resin, an ultraviolet curable resin, or the like.

The driving integrated circuit DIC may be disposed on an area of the display substrate SUB_DA positioned in a relatively lower portion. The driving integrated circuit DIC may be mounted on the display substrate SUB_DA by a chip bonding process or a surface mounting process, and may be bonded to signal supply terminals and signal input terminals.

The driving integrated circuit DIC may generate a data signal and a gate signal based on image data and a timing synchronization signal supplied from the outside through the signal input terminals. The driving integrated circuit DIC may supply the generated data signal and gate signal to a corresponding signal supply terminal to drive each pixel PXL, to display a first sub-image IM21 corresponding to the image data in the first display area DA1.

The first flexible circuit board FPC1 may be disposed on another area of the display substrate SUB_DA positioned in a relatively lower portion. The flexible printed circuit (FPC) may be applied to the first flexible circuit board FPC1, and driving elements for supplying the image data and the timing synchronization signals input from the outside to the driving integrated circuit DIC may be formed in a surface mounting method, and a protection cap for protecting the driving elements may be formed.

The driving integrated circuit DIC may be electrically connected to a battery BAT. As an embodiment, the battery BAT may be disposed on the driving integrated circuit DIC, but is not limited to a disposition position. For example, the battery BAT may be positioned in a portion lower than the driving integrated circuit DIC.

The battery BAT may supply power required to drive the first display device DV1. The battery BAT may be charged through external power.

The battery BAT may be electrically connected to a first antenna member WPT1. As an embodiment, the first antenna member WPT1 may correspond to a wireless power transfer (hereinafter, WPT) antenna for wireless charging.

The first antenna member WPT1 may be positioned in a portion lower than the battery BAT.

A second flexible circuit board FPC2 may be disposed on the first antenna member WPT1. The flexible printed circuit (FPC) may be applied to a second flexible circuit board FPC2. Wirings for supplying a power signal may be formed in a surface mounting method, and a protection cap for protecting the wirings may be formed.

A connection member CN may be disposed between the battery BAT and the first antenna member WPT1. The connection member CN may be a flexible printed circuit (FPC) or a chip on film (COF).

Although not clearly shown, the connection member CN may electrically connect between an upper surface of the display substrate SUB_DA, the battery BAT, and the first antenna member WPT1.

A second antenna member WPT2 may be disposed on the connection member CN. The second antenna member WPT2 may be disposed on the connection member CN so that an upper surface of the second antenna member WPT2 faces a side surface of the first display device DV1.

The second antenna member WPT2 may be one of a WPT antenna, a magnetic secure transmission (MST) antenna, a near field communication (NFC) antenna, and an RFID antenna for wireless charging, or may be a 3-combo antenna in which the WPT antenna, the MST antenna, and the NFC antenna is formed in a combo form. In case that the second antenna member WPT2 is the WPT antenna, a frequency band may be in a range of about 100 kHz to about 300 kHz. In case that the second antenna member WPT2 is the NFC antenna, the frequency band may be in a range of about 10 MHz to about 20 MHz.

A window member WD may be disposed on the first display device DV1 and may be positioned on the polarization layer POL. For example, the window member WD may be formed of glass, sapphire, plastic, or the like. The window member WD may overlap both of the first display area DA1 and the first non-display area NDA1 defined above in a plan view.

Although the window member WD is shown as a single layer, the window member WD may include multiple layers.

A black matrix BM may be disposed to overlap the first non-display area NDA1 on a rear surface of the window member WD. The black matrix BM may include a light absorption material or a light reflection material. For example, the black matrix BM may include a black colored resin, or a reflective metal such as chromium (Cr), or the like.

The black matrix BM may be positioned adjacent to the polarization layer POL.

A housing member FU may mount the above-described members, and may be coupled to the window member WD.

In case that the housing member FU and the window member WD are coupled, a first buffer member BF1 may be disposed between the black matrix BM and the housing member FU in order to reduce a step difference or facilitate the coupling.

In some embodiments, a second buffer member BF2 may be disposed between the battery BAT, the first antenna member WPT1, and the second flexible circuit board FPC2. As an embodiment, the first buffer member BF1 and the second buffer member BF2 may include a resin.

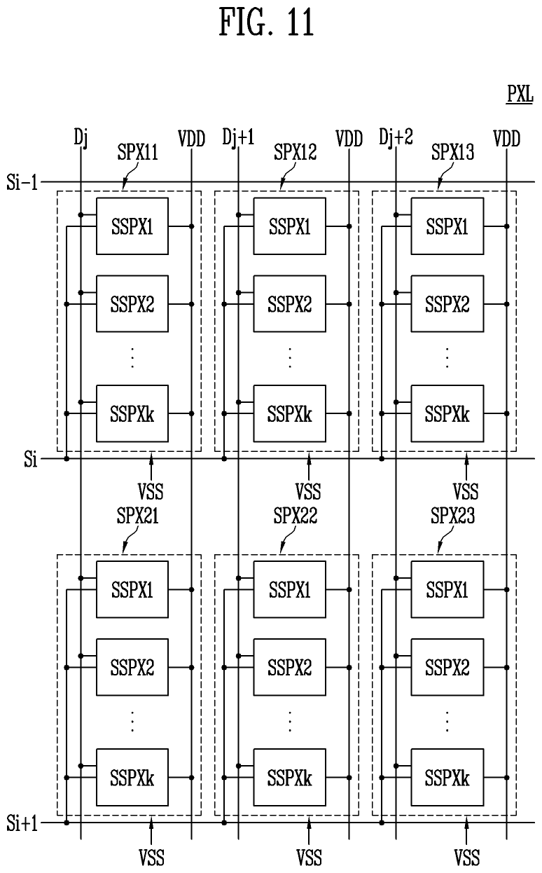

FIG. 11 is a schematic diagram of an equivalent circuit illustrating an example of a sub-pixel included in the first display device of FIG. 9. FIG. 11 shows the first to sixth sub-pixels SPX11 to SPX23 included in the first display device DV1 of FIG. 9.

Referring to FIG. 11, as an embodiment, each of the sub-pixels SPX11 to SPX23 may include pixels (or unit pixels) SSPX11, SSPX12, and SSPX13.

Since the first to sixth sub-pixels SPX11 to SPX23 are substantially identical to each other except that the first to sixth sub-pixels SPX11 to SPX23 are electrically connected to corresponding data lines Dj, Dj+1, and Dj+2 and corresponding scan lines Si and Si+1, respectively, the first to sixth sub-pixels SPX11 to SPX23 are described inclusively based on the first sub-pixel SPX11.

The first to sixth sub-pixels SPX11 to SPX23 may be disposed in areas partitioned by scan lines Si−1, Si, and Si+1 (where i is a positive integer) and data lines Dj, Dj+1, and Dj+2 (where j is a positive integer), respectively. For example, the first sub-pixel SPX11 may be disposed in an area partitioned by the (i−1)-th and i-th scan lines Si−1 and Si and the j-th and (j+1)-th data lines Dj and Dj+1. However, the disposition of the first to sixth sub-pixels SPX11 to SPX23 is not limited thereto.

The first sub-pixel SPX11 may be electrically connected to the scan line Si and the data line Dj, and may also be electrically connected to a first power line and a second power line. First power VDD may be applied to the first power line, second power VSS may be applied to the second power line, and each of the first and second power lines may be a common line electrically connected to the sub-pixels. The first and second powers VDD and VSS may have different potentials so that the first sub-pixel SPX11 emits light, and the first power VDD may have a voltage level higher than a voltage level of the second power VSS.

As an embodiment, the first sub-pixel SPX11 may include at least one unit pixels SSPX1 to SSPXk (where k is a positive integer).

Each of the unit pixels SSPX1 to SSPXk may be electrically connected to the scan line Si and the data line Dj, and may also be electrically connected to the first power line and the second power line. Each of the unit pixels SSPX1 to SSPXk may emit light with a luminance corresponding to a data signal transmitted through the data line Dj in response to a scan signal transmitted through the scan line Si. The unit pixels SSPX1 to SSPXk may include substantially a same pixel structure or pixel circuit.

For example, the first sub-pixel SPX11 may include unit pixels SSPX1 to SSPXk that independently emit light in response to a scan signal and a data signal.

As an embodiment, each of the unit pixels S SPX1 to SSPXk (or the sub-pixels SPX11 to SPX23) may be configured as an active pixel. However, a type, a structure, and/or a driving method of the unit pixel applicable to the first display device DV1 of the disclosure are/is not particularly limited thereto. For example, the unit pixel may be configured as a pixel of the first display device DV1 having various passive or active structures.

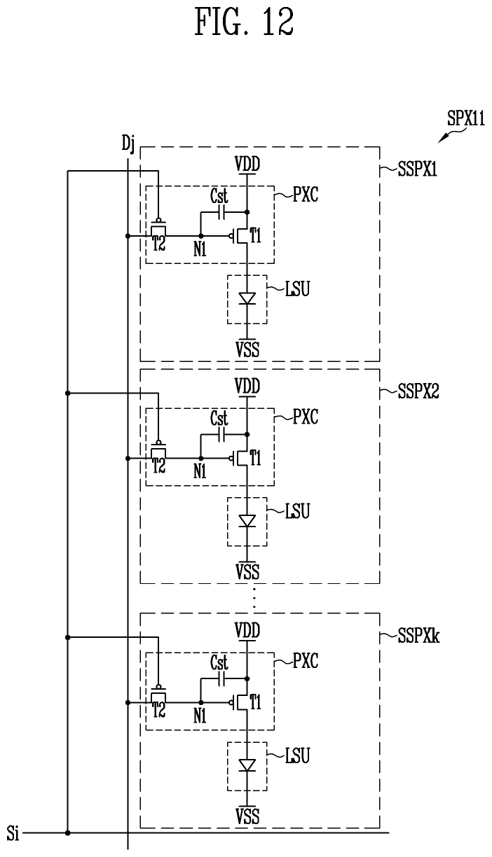

FIGS. 12 to 18 are schematic diagrams of equivalent circuits illustrating an example that may be applied to the unit pixel included in the sub-pixel of FIG. 11.

The description is based on a unit pixel in each drawing, and similar contents may be applied to first to k-th unit pixels SSPX1 to SSPXk shown in FIG. 12, and thus detailed description of the same elements is omitted. For example, the first to k-th unit pixels SSPX1 to SSPXk shown in FIG. 11 may have substantially the same or similar structure, and the first unit pixel SSPX1 shown in FIGS. 12 to 18 may be an example, and may be applied to any one of the first to k-th unit pixels SSPX1 to SSPXk of FIG. 11.

Referring to FIG. 12, the first unit pixel SSPX1 may include a light source unit (or light source part) LSU that emits light with a luminance corresponding to the data signal. The first unit pixel SSPX1 may selectively further include a pixel circuit PXC for driving the light source part LSU.

According to an embodiment, the light source part LSU may include multiple light emitting elements LD electrically connected between the first power VDD and the second power VSS. In an embodiment, the light emitting elements LD may be electrically connected in a parallel structure each other, but are not limited thereto. For example, the light emitting elements LD may be electrically connected in a parallel structure between the first power VDD and the second power VSS.

The first power VDD and the second power VSS may have different potentials so that the light emitting elements LD may emit light. For example, the first power VDD may be set as a high potential power and the second power VSS may be set as a low potential power. A potential difference between the first power VDD and the second power VSS may be set to be equal to or greater than a threshold voltage of the light emitting elements LD during an emission period of the first part pixel SSPX1 (or the first sub-pixel SPX11).

Although FIG. 12 shows an embodiment in which the light emitting elements LD are electrically connected in parallel to each other in the same direction (e.g., a forward direction) between the first power VDD and the second power VSS, the disclosure is not limited thereto. For example, some of the light emitting elements LD may be electrically connected in a forward direction between the first power VDD and the second power VSS to form respective effective light sources, and another portion of the light emitting elements LD may be electrically connected in a reverse direction. As another example, the first unit pixel SSPX1 may include only a single light emitting element LD (for example, a single effective light source electrically connected in the forward direction between the first power VDD and the second power VSS).

According to an embodiment, an end of each of the light emitting elements LD may be commonly connected to a corresponding pixel circuit PXC through a first electrode, and may be electrically connected to the first power VDD through the pixel circuit PXC and the first power line. Another end of each of the light emitting elements LD may be commonly connected to the second power VSS through a second electrode and the second power line.

The light source part LSU may emit light with a luminance corresponding to a driving current supplied through a corresponding pixel circuit PXC. Therefore, an image may be displayed in the first display area DA1 (refer to FIGS. 1 and 9).

The pixel circuit PXC may be electrically connected to the scan line Si and the data line Dj of a corresponding sub-pixel (e.g., the first sub-pixel SPX11). For example, in case that the first sub-pixel SPX11 is disposed in an i-th row and a j-th column of the first display area DA1, the pixel circuit PXC of the unit pixel (e.g., SSPX1, SSPX2, and SSPXk) may be electrically connected to the i-th scan line Si and the j-th data line Dj of the first display area DA1.

The pixel circuit PXC may include first and second transistors T1 and T2 and a storage capacitor Cst.

The first transistor T1 (or a driving transistor) may be electrically connected between the first power VDD and the light source part LSU. A gate electrode of the first transistor T1 may be electrically connected to a first node N1. The first transistor T1 may control a driving current supplied to the light source part LSU in response to a voltage of the first node N1.

The second transistor T2 (or a switching transistor) may be electrically connected between the data line Dj and the first node N1. A gate electrode of the second transistor T2 may be electrically connected to the scan line Si.

The second transistor T2 may be turned on in response to a scan signal of a gate-on voltage (e.g., a low voltage) from the scan line Si to electrically connect the data line Dj and the first node N1 to each other.

A data signal of a corresponding frame may be supplied to the data line Dj in every frame period, and the data signal may be transferred to the first node N1 via the second transistor T2. Accordingly, a voltage corresponding to the data signal may be charged in the storage capacitor Cst.

An electrode of the storage capacitor Cst may be electrically connected to the first power VDD, and another electrode of the storage capacitor Cst may be electrically connected to the first node N1. The storage capacitor Cst may charge the voltage corresponding to the data signal supplied to the first node N1 during each frame period, and maintain the charged voltage until the data signal of the next frame is supplied.

In FIG. 12, the transistors included in the pixel circuit PXC (e.g., the first and second transistors T1 and T2) are shown as P-type transistors, but the disclosure is not limited thereto. For example, at least one of the first and second transistors T1 and T2 may be changed to an N-type transistor.

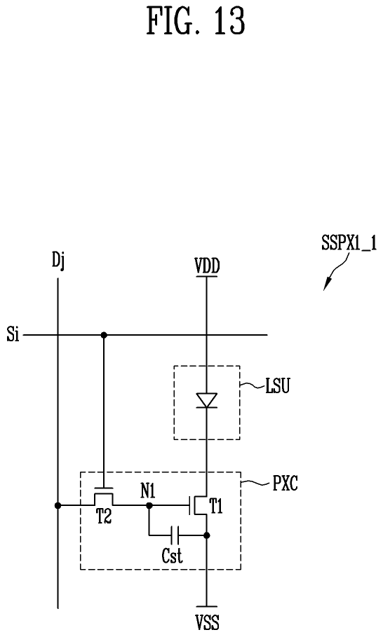

For example, as shown in FIG. 13, both of the first and second transistors T1 and T2 may be N-type transistors. The gate-on voltage of the scan signal for writing the data signal, which is supplied to the data line Dj, to a first unit pixel SSPX1_1 during each frame period may be a high level voltage. Similarly, a voltage of the data signal for turning on the first transistor T1 may be a voltage of a waveform opposite to that of the embodiment of FIG. 12. For example, in the embodiment of FIG. 13, a data signal having a higher voltage level may be supplied as a grayscale value to be expressed is increased.

A configuration and an operation of the first unit pixel SSPX1_1 shown in FIG. 13 are substantially similar to those of the first unit pixel SSPX1 of FIG. 12, except that a connection position of some circuit elements and voltage levels of control signals (e.g., the scan signal and the data signal) are changed according to change in a transistor type. Therefore, a detailed description of the first unit pixel SSPX1_1 of FIG. 13 is omitted.

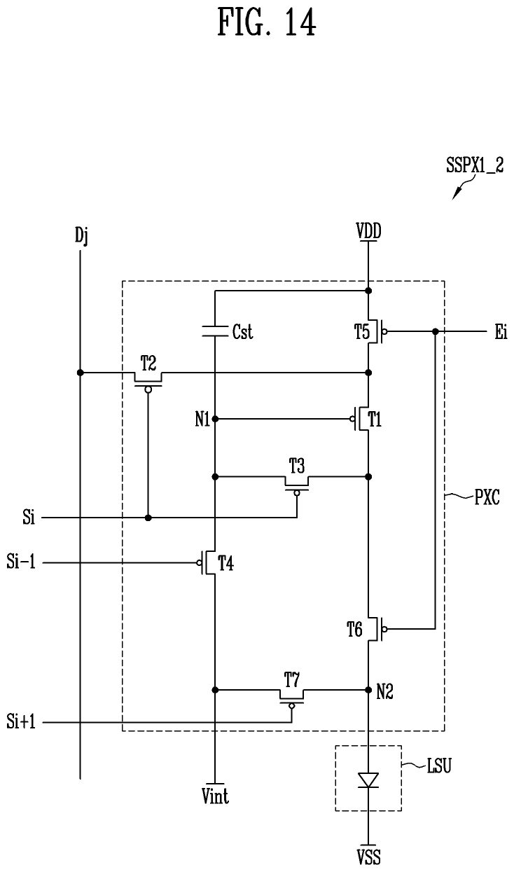

The structure of the pixel circuit PXC is not limited to the embodiment shown in FIGS. 12 and 13. For example, the pixel circuit PXC may be configured as a pixel circuit of various structures and/or driving methods. For example, the pixel circuit PXC may be configured as in an embodiment shown in FIG. 14.

Referring to FIG. 14, a pixel circuit PXC in a first unit pixel SSPX1_2 may be further electrically connected to at least another scan line (or control line) in addition to the corresponding scan line Si. For example, the pixel circuit PXC of the sub-pixel SPX (or the unit pixel SSPX1_2 included therein) disposed in the i-th row of the first display area DA1 may be further electrically connected to an (i−1)-th scan line Si−1 and/or an (i+1)-th scan line Si+1. According to an embodiment, the pixel circuit PXC may be further electrically connected to another power in addition to the first power VDD and the second power VSS. For example, the pixel circuit PXC may also be electrically connected to an initialization power Vint.

According to an embodiment, the pixel circuit PXC may include seven transistors T1 to T7. The pixel circuit PXC may include the first to seventh transistors T1 to T7 and a storage capacitor Cst.

The first transistor T1 may be electrically connected between the first power VDD and the light source part LSU. An electrode (e.g., a source electrode) of the first transistor T1 may be electrically connected to the first power VDD through the fifth transistor T5, and another electrode (e.g., a drain electrode) of the first transistor T1 may be electrically connected to an electrode (e.g., a first electrode of a corresponding sub-pixel SPX) of the light source part LSU via the sixth transistor T6. A gate electrode of the first transistor T1 may be electrically connected to a first node N1. The first transistor T1 may control the driving current supplied to the light source part LSU in response to a voltage of the first node N1.

The second transistor T2 may be electrically connected between the data line Dj and the electrode of the first transistor T1. A gate electrode of the second transistor T2 may be electrically connected to the corresponding scan line Si. The second transistor T2 may be turned on to electrically connect the data line Dj to the electrode of the first transistor T1 in case that the scan signal of the gate-on voltage is supplied from the scan line Si. Therefore, in case that the second transistor T2 is turned on, the data signal supplied from the data line Dj may be transferred to the first transistor T1.

The third transistor T3 may be electrically connected between the another electrode (e.g., the drain electrode) of the first transistor T1 and the first node N1. A gate electrode of the third transistor T3 may be electrically connected to the corresponding scan line Si. The third transistor T3 may be turned on to electrically connect the first transistor T1 in a diode form in case that the scan signal of the gate-on voltage is supplied from the scan line Si.

The fourth transistor T4 may be electrically connected between the first node N1 and the initialization power Vint. A gate electrode of the fourth transistor T4 may be electrically connected to a previous scan line, for example, the (i−1)-th scan line Si−1. The fourth transistor T4 may be turned on to transfer a voltage of the initialization power Vint to the first node N1 in case that the scan signal of the gate-on voltage is supplied to the (i−1)-th scan line Si−1. The voltage of the initialization power Vint may be equal to or less than a lowest voltage of the data signal.

The fifth transistor T5 may be electrically connected between the first power VDD and the first transistor T1. A gate electrode of the fifth transistor T5 may be electrically connected to a corresponding emission control line, for example, an i-th emission control line Ei. The fifth transistor T5 may be turned off in case that an emission control signal of a gate-off voltage (e.g., a high voltage) is supplied to the emission control line Ei, and may be turned on in other cases.

The sixth transistor T6 may be electrically connected between the first transistor T1 and the first electrode of the light source part LSU. A gate electrode of the sixth transistor T6 may be electrically connected to a corresponding emission control line, for example, the i-th emission control line Ei. The sixth transistor T6 may be turned off in case that the emission control signal of the gate-off voltage is supplied to the emission control line Ei, and may be turned on in other cases.

The seventh transistor T7 may be electrically connected between the first electrode of the light source part LSU and the initialization power Vint (or a third power line transmitting the initialization power). A gate electrode of the seventh transistor T7 may be electrically connected to any one of next scan lines, for example, the (i+1)-th scan line Si+1. The seventh transistor T7 may be turned on to supply the voltage of the initialization power Vint to the first electrode of the light source part LSU in case that the scan signal of the gate-on voltage is supplied to the (i+1)-th scan line Si+1. A voltage of the first electrode of the light source part LSU may be initialized during each initialization period in which the voltage of the initialization power Vint is transferred to the light source part LSU.

A control signal for controlling an operation of the seventh transistor T7 may be variously changed. For example, the gate electrode of the seventh transistor T7 may be electrically connected to a scan line of a corresponding horizontal line, for example, the i-th scan line Si. The seventh transistor T7 may be turned on to supply the voltage of the initialization power Vint to the electrode of the light source part LSU in case that the scan signal of the gate-on voltage is supplied to the i-th scan line Si.

The storage capacitor Cst may be electrically connected between the first power VDD and the first node N1. The storage capacitor Cst may store a voltage corresponding to the data signal supplied to the first node N1 and a threshold voltage of the first transistor T1 in each frame period.

In FIG. 14, all of the transistors included in the pixel circuit PXC, for example, the first to seventh transistors T1 to T7 are shown as P-type transistors, but the disclosure is not limited thereto. For example, at least one of the first to seventh transistors T1 to T7 may be changed to an N-type transistor.

According to an embodiment, the pixel circuit PXC may be further electrically connected to a line in addition to the data line Dj.

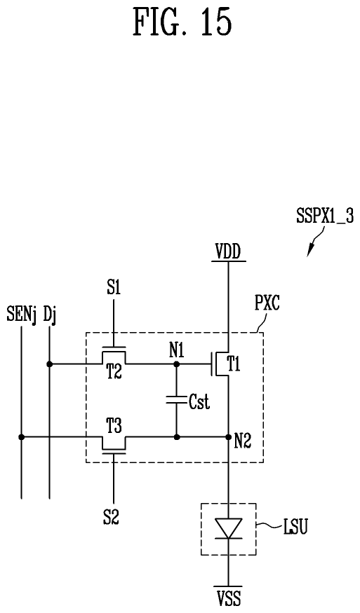

Referring to FIG. 15, a pixel circuit PXC in a first unit pixel SSPX1_3 may be electrically connected to a sensing line SENj. The pixel circuit PXC may include first to third transistors T1 to T3 and a storage capacitor Cst. Since the first and second transistors T1 and T2 and the storage capacitor Cst are substantially the same as or similar to the first and second transistors T1 and T2 and the storage capacitor Cst described with reference to FIG. 13, respectively, detailed description of the same elements is omitted.

The third transistor T3 may be electrically connected between the sensing line SENj and the second node N2. A gate electrode of the third transistor T3 may be electrically connected to a second scan line S2 different from a first scan line S1 (e.g., a (i+1)-th scan line Si+1 different from a i-th scan line Si).

The light source part LSU may be electrically connected between the second node N2 and the second power line (e.g., a power line to which the second power VSS is applied).

The third transistor T3 may be turned on in response to a scan signal of a gate-on voltage transmitted from the second scan line S2 to electrically connect the sensing line SENj and the second node N2.

For example, in case that the third transistor T3 is turned on in a state in which a driving current corresponding to a reference voltage flows through the first transistor T1, the driving current flowing through the first transistor T1 may be supplied to an external sensing device through the third transistor T3 and the sensing line SENj, and a signal corresponding to a characteristic (e.g., Vth) of the first transistor T1 may be output to the outside through the sensing line SENj based on the driving current.

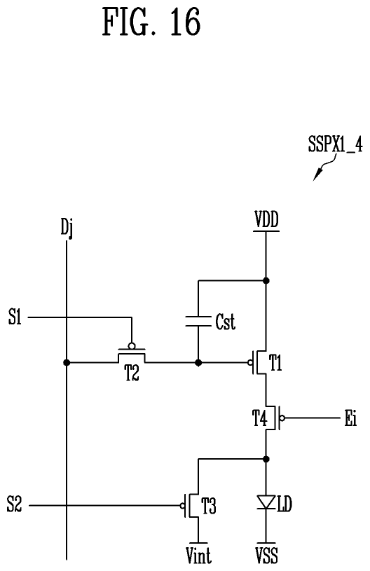

Referring to FIG. 16, a pixel circuit PXC in a first unit pixel SSPX1_4 may be electrically connected to an initialization voltage line to which the initialization power Vint is provided. The pixel circuit PXC may include first to fourth transistors T1 to T4 and a storage capacitor Cst. Since the first to fourth transistors T1 to T4 and the storage capacitor Cst are substantially the same as or similar to the first and second transistors T1 and T2 described with reference to FIG. 12, and the seventh and sixth transistors T7 and T6 and the storage capacitor Cst described with reference to FIG. 14, respectively, detailed description of the same elements is omitted.

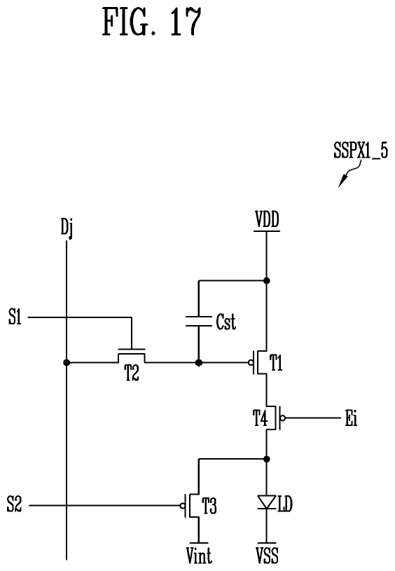

Referring to FIG. 17, a first unit pixel SSPX1_5 may be applied similarly to the first unit pixel SSPX1_4 of FIG. 16, and the second transistor T2 may be an N-type transistor.

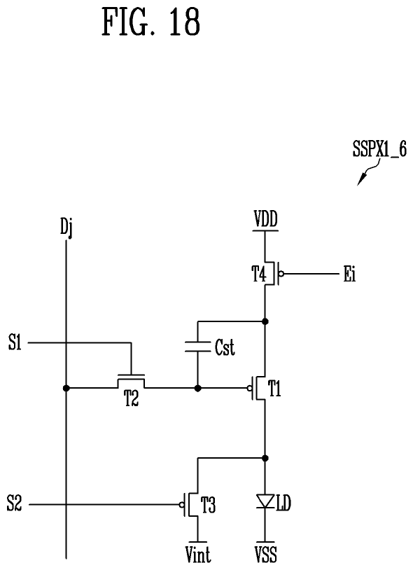

Referring to FIG. 18, a first unit pixel SSPX1_6 may be applied similarly to the first unit pixel SSPX1_4 of FIG. 16, the second transistor T2 may be an N-type transistor, and the fourth transistor T4 may be applied identically or similarly to the fifth transistor T5 described with reference to FIG. 14.

A structure of the first unit pixel SSPX1 applicable to the disclosure is not limited to the embodiments shown in FIGS. 12 to 18, and the first unit pixel SSPX1 may have various structures. For example, the pixel circuit PXC included in the first unit pixel SSPX1 may be configured with a pixel circuit of various structures and/or driving methods. The first unit pixel SSPX1 may be configured in a passive light emitting panel or the like. The pixel circuit PXC may be omitted, and each of the first and second electrodes of the light source part LSU may be directly connected to the scan line Si, the data line Dj, the power line, the control line, and/or the like.

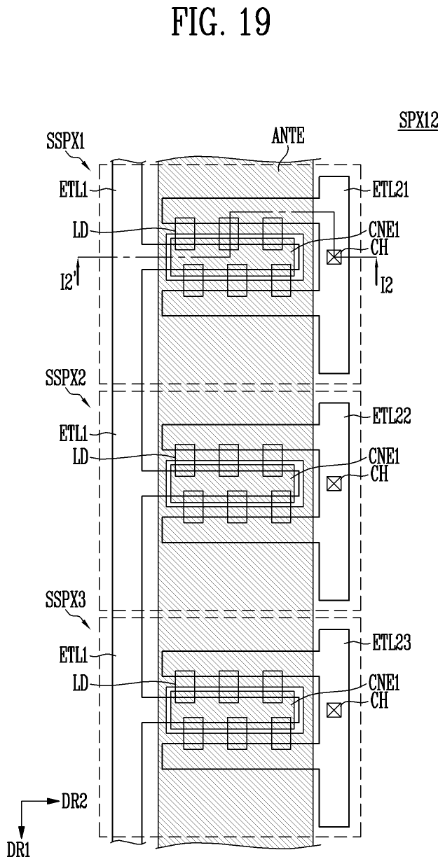

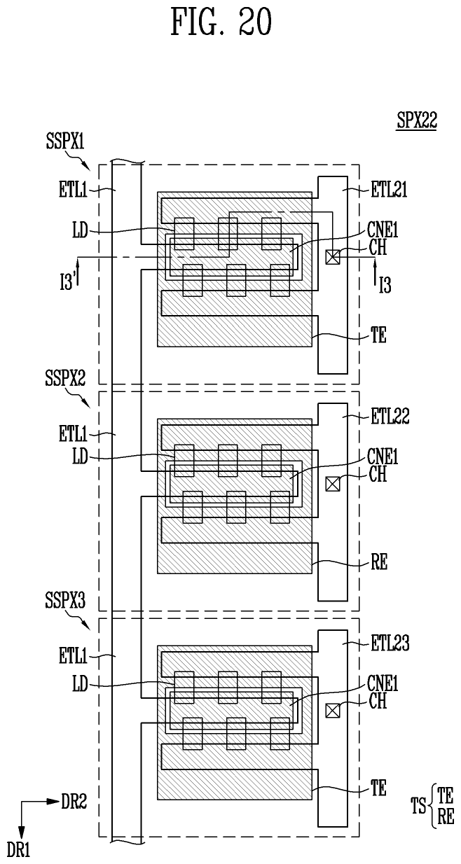

FIG. 19 is a plan layout diagram schematically illustrating a disposition of a sub-pixel included in the first display device of FIG. 9. FIG. 20 is a plan layout diagram schematically illustrating a disposition of another sub-pixel included in the first display device of FIG. 9. FIG. 19 shows the second sub-pixel SPX12 among sub-pixels disposed in the first sub-display area DA11, and FIG. 20 shows the fifth sub-pixel SPX22 among sub-pixels disposed in the second sub-display area DA12.

In FIGS. 19 and 20, a structure of unit pixels SSPX1 to SSPX3 is shown based on the light source unit LSU (refer to FIGS. 12 to 18) (or a light emitting element layer) included in the unit pixels SSPX1 to SSPX3 of each of the sub-pixels SPX12 and SPX22. Since the first to third unit pixels SSPX1 to SSPX3 are substantially identical to each other, the light source unit LSU is described based on the first unit pixel SSPX1.

Referring to FIG. 19, the first unit pixel SSPX1 of the second sub-pixel SPX12 may include a first electrode ETL1 and second electrodes ETL21, ETL22, and ETL23 disposed to be spaced apart from each other, and at least one light emitting element LD electrically connected between the first and second electrodes ETL1, ETL21, ETL22, and ETL23.

According to an embodiment, the light emitting elements LD included in the same unit pixels SSPX1 to SSPX3 may emit light of a same color. According to an embodiment, the first to third unit pixels SSPX1 to SSPX3 may define an emission area emitting light of different colors. For example, the first unit pixel SSPX1 may include light emitting elements LD emitting red light, the second unit pixel SSPX2 may include light emitting elements LD emitting green light, and the third unit pixel SSPX3 may include light emitting elements LD emitting blue light. As another example, all of the first to third unit pixels SSPX1 to SSPX3 may include light emitting elements LD emitting blue light. In order to configure a full-color pixel PXL, a light conversion layer and/or a color filter for converting a color of light emitted from a corresponding unit pixel may be disposed on at least a portion of the first to third unit pixels SSPX1 to SSPX3.

As an embodiment, the first electrode ETL1 may be an electrode shared by the first to third unit pixels SSPX1 to SSPX3. The first to third unit pixels SSPX1 to SSPX3 may be disposed along the first direction DR1.

The second electrodes ETL21, ETL22, and ETL23 may be spaced apart from the first electrode ETL1 at a side in the second direction DR2. The second electrodes ETL21, ETL22, and ETL23 in the first to third unit pixels SSPX1 to SSPX3 may be arranged in the first direction DR1.

The first and second electrodes ETL1, ETL21, ETL22, and ETL23 may be spaced apart from each other by a distance and disposed side by side (or parallel to each other).

As an embodiment, the first electrode ETL1 may be a cathode electrode electrically connected to the second power VSS. The second electrodes ETL21, ETL22, and ETL23 may be anode electrodes electrically connected to the first power VDD. The light emitting elements LD having one end and another end electrically connected to the first electrode ETL1 and the second electrodes ETL21, ETL22, and ETL23, respectively, are disposed, and thus the first electrode ETL1 and each of the second electrodes ETL21, ETL22, and ETL23 may be electrically connected.

As an embodiment, an emission area may be defined per unit pixel (e.g., SSPX1). The emission area may be divided by a non-emissive area. Although not clearly shown, a pixel defining layer (or a bank, a light blocking pattern), or the like blocking the light emitted from the light emitting element LD from being transmitted to another area may overlap the non-emission area.

As an embodiment, the second sub-pixel SPX12 may include a first contact electrode CNE1 electrically connecting the first electrode ETL1 and the end of the light emitting elements LD. The first contact electrode CNE1 may overlap with least a partial area of the first electrode ETL1 in a plan view.

The second sub-pixel SPX12 may include an antenna pattern ANTE simultaneously formed with the first contact electrode CNE1 by the same process as the first contact electrode CNE1. The antenna pattern ANTE may be electrically separated from and insulated from the first contact electrode CNE1. The antenna pattern ANTE may have a shape surrounding the first contact electrodes CNE1 formed for each unit pixel. The antenna pattern ANTE shown in the figure may correspond to the antenna pattern ANTE of FIG. 10.

The antenna pattern ANTE may overlap each of the unit pixels SSPX1 to SSPX3 in a plan view. The antenna pattern ANTE may be formed for each sub-pixel (e.g., SPX11, SPX12, SPX13, and SPX21, refer to FIG. 9) in the first sub-display area DA11. The antenna pattern ANTE may be an electrode pattern formed for each sub-pixel. Although not clearly shown, the antenna patterns ANTE positioned in adjacent sub-pixels may be electrically connected to each other. However, a shape of the antenna pattern ANTE is not limited thereto, and the antenna pattern ANTE may be formed for each of the unit pixels SSPX1 to SSPX3, and in this case, the antenna patterns ANTE may be electrically connected to each other through a separate connection pattern (not shown).

Referring to FIG. 20, in the fifth sub-pixel SPX22, touch electrode patterns TS may be formed at a position corresponding to the antenna pattern ANTE instead of the antenna pattern ANTE formed in the second sub-pixel SPX12 of FIG. 19.

The touch electrode patterns TS may be formed for each sub-pixel (e.g., SPX23 and SPX22, refer to FIG. 9) in the second sub-display area DA12, respectively. The touch electrode patterns TS may be formed for each of the unit pixels SSPX1 to SSPX3, respectively, and adjacent touch electrode patterns TS may be electrically separated and insulated. In the figure, the touch electrode patterns TS may correspond to the touch electrode patterns TS of FIG. 10.

As an embodiment, some of the touch electrode patterns TS may correspond to a driving electrode TE through which the driving signal flows, and a remaining portion of the touch electrode patterns TS may correspond to a sensing electrodes RE through which a sensing signal flows. The driving electrode TE and the sensing electrode RE may sense an external input (or touch event) with a mutual-cap or self-cap method.

However, a disposition shape of the touch electrode patterns TS is not limited thereto and may be formed for each sub-pixel. In another embodiment, the touch electrode patterns TS in at least some sub-pixels in the second sub-display area DA12 may be changed to a piezoelectric sensor pattern FS (see FIG. 10).

Since a disposition structure of the first and second electrodes ETL1, ETL21, ETL22, and ETL23, and the first contact electrode CNE1 of the fifth sub-pixel SPX22 is the same as that in the second sub-pixel SPX12, detailed description of the same elements is omitted.

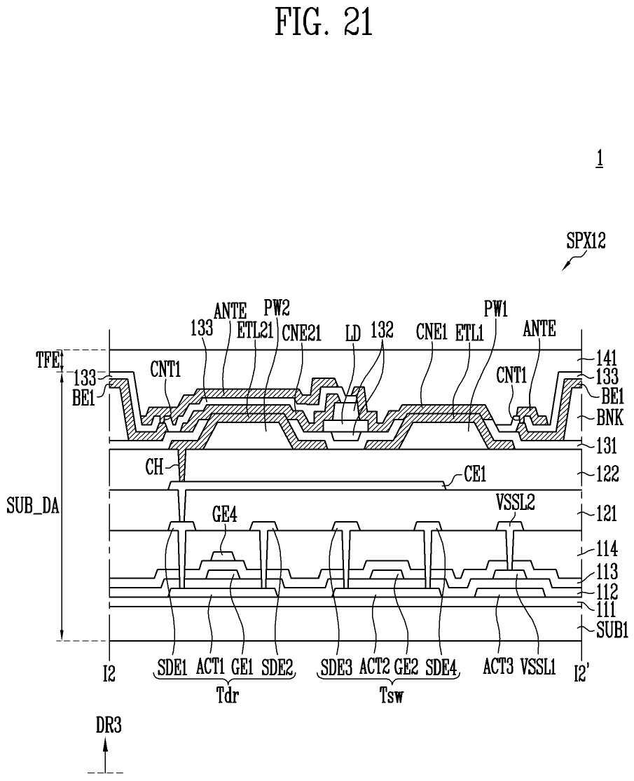

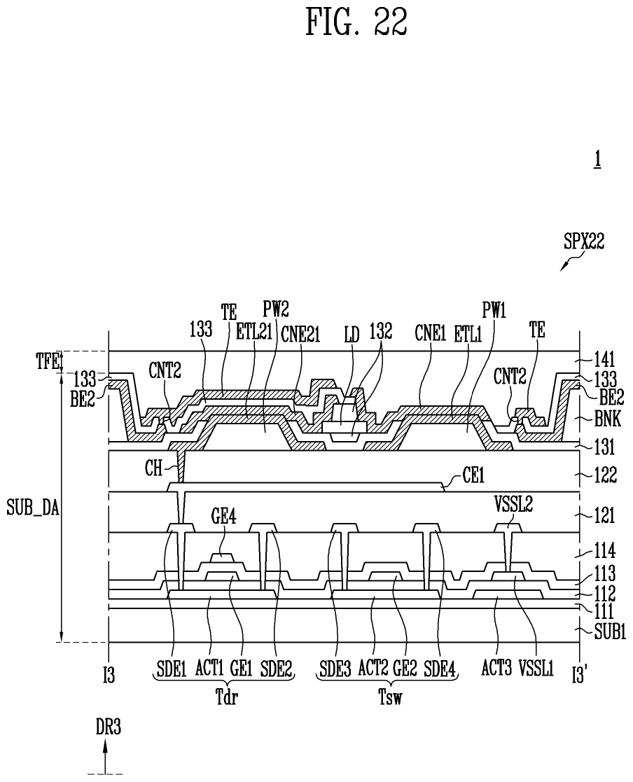

FIG. 21 is a schematic cross-sectional view of the display substrate to the encapsulation layer corresponding to line I2-I2′ of FIG. 19 in the first display device. FIG. 22 is a schematic cross-sectional view of the display substrate to the encapsulation layer corresponding to line I3-I3′ of FIG. 20 in the first display device.

Referring to FIGS. 21 and 22, the first display device DV1 may include a base layer SUB1 disposed under the display substrate SUB_DA. Since a description of the base layer SUB1 is described above with reference to FIG. 9, detailed description of the same elements is omitted.

A first buffer layer 111 may be disposed on the base layer SUB1. The first buffer layer 111 may function to smooth (or planarize) a surface of the base layer SUB1 and prevent penetration of moisture or external air. The first buffer layer 111 may be an inorganic layer. The first buffer layer 111 may be a single layer or multiple layers.

Transistors Tdr and Tsw may be disposed on the first buffer layer 111. Each of the transistors Tdr and Tsw may be a thin film transistor. The two transistors Tdr and Tsw shown in the figure correspond to a driving transistor and a switch transistor, respectively.

Each of the transistors Tdr and Tsw may include semiconductor patterns ACT1 and ACT2, gate electrodes GE1 and GE2, source electrodes SDE2 and SDE4, and drain electrodes SDE1 and SDE3, respectively. For example, the first transistor Tdr that is the driving transistor may include a first semiconductor pattern ACT1, a first gate electrode GE1, a first source electrode SDE2, and a first drain electrode SDE1. The second transistor Tsw that is the switch transistor may include a second semiconductor pattern ACT2, a second gate electrode GE2, a second source electrode SDE4, and a second drain electrode SDE3.

For example, a semiconductor layer may be disposed on the first buffer layer 111. The semiconductor layer may include the first semiconductor pattern ACT1 and the second semiconductor pattern ACT2 described above. The semiconductor layer may further include a third semiconductor pattern ACT3.

The semiconductor layer may include at least one of amorphous silicon, poly silicon, low temperature poly silicon, and an organic semiconductor. In another embodiment, the semiconductor layer may be an oxide semiconductor. Although not clearly shown, the semiconductor layer may include a channel region, and a source region and a drain region disposed at both sides of the channel region and doped with impurities.

A first gate insulating layer 112 may be disposed on the semiconductor layer. The first gate insulating layer 112 may be an inorganic layer. The first gate insulating layer 112 may be a single layer or multiple layers.

A first conductive layer may be disposed on the first gate insulating layer 112. The first conductive layer may include the first gate electrode GE1 and the second gate electrode GE2 described above. The first conductive layer may further include a first low power pattern VSSL1. The first conductive layer may be formed of a metallic material having conductivity (e.g., electrical conductivity). For example, the first conductive layer may include molybdenum (Mo), aluminum (Al), copper (Cu), or titanium (Ti). The first conductive layer may be a single layer or multiple layers.

The first low power pattern VSSL1 may be electrically connected to the second power line. The first low power pattern VSSL1 may be disposed in the first display area DA1 and may overlap the third semiconductor pattern ACT3 in a plan view.

A second gate insulating layer 113 may be disposed on the first conductive layer. The second gate insulating layer 113 may be an inorganic layer. The second gate insulating layer 113 may be a single layer or multiple layers.

A second conductive layer may be disposed on the second gate insulating layer 113. The second conductive layer may include a third gate electrode GE4. The third gate electrode GE4 may be a gate electrode of another transistor which is not shown, but is not limited thereto. The second conductive layer may be formed of a metallic material having conductivity (e.g., electrical conductivity). For example, the second conductive layer may include molybdenum (Mo), aluminum (Al), copper (Cu), or titanium (Ti). The second conductive layer may be a single layer or multiple layers.

An interlayer insulating layer 114 may be disposed on the second conductive layer. The interlayer insulating layer 114 may be an organic layer or an inorganic layer. The interlayer insulating layer 114 may be a single layer or multiple layers.

A third conductive layer may be disposed on the interlayer insulating layer 114. The third conductive layer may include the source electrodes SDE2 and SDE4 and the drain electrodes SDE1 and SDE3 described above. The third conductive layer may further include a second low power pattern VSSL2. The third conductive layer may be formed of a metallic material having conductivity (e.g., electrical conductivity). For example, the source electrodes SDE2 and SDE4, the drain electrodes SDE1 and SDE3, and the second low power pattern VSSL2 may include aluminum (Al), copper (Cu), titanium (Ti), or molybdenum (Mo).

The second low power pattern VSSL2 may be electrically connected to the second power line. The second low power pattern VSSL2 may contact the first low power pattern VSSL1 through a contact hole passing the second gate insulating layer 113 and the interlayer insulating layer 114. The second low power pattern VSSL2 may be disposed in the first display area DA1 and may overlap the first low power pattern VSSL1 and the third semiconductor pattern ACT3 in a plan view.

The source electrodes SDE2 and SDE4 and the drain electrodes SDE1 and SDE3 are not limited to names thereof. In another embodiment, the source electrodes SDE2 and SDE4 shown in FIGS. 21 and 22 may perform a function of a drain electrode, and the drain electrodes SDE1 and SDE3 shown in FIGS. 21 and 22 may perform a function of a source electrode.

The source electrodes SDE2 and SDE4 and the drain electrodes SDE1 and SDE3 may be respectively connected to the source regions and the drain regions of each of corresponding semiconductor patterns ACT1 and ACT2 through a contact hole passing through the interlayer insulating layer 114, the second gate insulating layer 113, and the first gate insulating layer 112.

Although not shown separately, the first display device DV1 may further include a storage capacitor disposed on the base layer SUB1.

A first protection layer 121 may be disposed on the third conductive layer. The first protection layer 121 may cover a circuit portion including the transistors Tdr and Tsw. The first protection layer 121 may also be disposed in at least a portion of the first non-display area NDA1. The first protection layer 121 may be a passivation layer or a planarization layer. The passivation layer may include SiO₂, SiNₓ, or the like, and the planarization layer may include a material such as acrylic resin or polyimide. The first protection layer 121 may include both the passivation layer and the planarization layer. The passivation layer may be disposed on the third conductive layer and the interlayer insulating layer 114, and the planarization layer may be disposed on the passivation layer. An upper surface of the first protection layer 121 may be flat.

A fourth conductive layer may be disposed on the first protection layer 121. The fourth conductive layer may include various conductive patterns and the like such as a power line, a signal line, and a connection electrode. In the drawing, the fourth conductive layer includes a first connection pattern CE1 disposed in the first display area DA1 as an example, but the disclosure is not limited thereto. The fourth conductive layer may be formed of a metallic material having conductivity (e.g., electrical conductivity). For example, the fourth conductive layer may include aluminum (Al), copper (Cu), titanium (Ti), and molybdenum (Mo).

The first connection pattern CE1 may contact any one of the source electrode SDE2 and the drain electrode SDE1 of the first transistor Tdr through a contact hole passing through the first protection layer 121.

A second protection layer 122 may be disposed on the fourth conductive layer. The second protection layer 122 may be a passivation layer or a planarization layer. The passivation layer may include SiO₂, SiNₓ, or the like, and the planarization layer may include a material such as acrylic resin or polyimide. The second protection layer 122 may include both the passivation layer and the planarization layer.

The second protection layer 122 may include an opening exposing an upper portion of a partial member of a partial fourth conductive layer included in the fourth conductive layer. For example, the second protection layer 122 may include an opening exposing at least a portion of the first connection pattern CE1.

In the specification, elements disposed from the base layer SUB1 to the second protection layer 122 are referred to as a pixel circuit layer. For example, the pixel circuit layer corresponds to layers including the transistors in the display substrate SUB DA.

The first display device DV1 may include first and second partition walls PW1 and PW2, the first and second electrodes ETL1 and ETL21, a first insulating layer 131, the light emitting elements LD, a second insulating layer 132, first and second contact electrodes CNE1 and CNE21, a third insulating layer 133, and a thin film encapsulation layer 141 sequentially disposed on the second protection layer 122.

The first and second partition walls PW1 and PW2 may be disposed on the pixel circuit layer (e.g., the second protection layer 122). The first and second partition walls PW1 and PW2 may protrude in the thickness direction (e.g., the third direction DR3) on the pixel circuit layer. According to an embodiment, the first and second partition walls PW1 and PW2 may have substantially a same height, but are not limited thereto. For example, protrusion heights of the first and second partition walls PW1 and PW2 may be in a range of about 1.0 μm to about 1.5 μm, respectively.

As an embodiment, the first partition wall PW1 may be disposed between the pixel circuit layer and the first electrode ETL1. The second partition wall PW2 may be disposed between the pixel circuit layer and each of the second electrodes ETL21, ETL22, and ETL23.

According to an embodiment, the first and second partition walls PW1 and PW2 may have various shapes. As an example, the first and second partition walls PW1 and PW2 may have a trapezoidal cross-sectional shape in which a width becomes narrower toward an upper portion thereof as shown in the drawing. Each of the first and second partition walls PW1 and PW2 may have an inclined surface on at least one side surface.

Although not shown, as another example, the first and second partition walls PW1 and PW2 may have a semi-circular or semi-elliptical cross-section in which a width becomes narrower toward an upper portion thereof. Each of the first and second partition walls PW1 and PW2 may have a curved surface on at least one side surface. For example, in the disclosure, the shape of the first and second partition walls PW1 and PW2 is not limited thereto, and may be variously changed. According to an embodiment, at least one of the first and second partition walls PW1 and PW2 may be omitted and/or a position thereof may be changed.

The first and second partition walls PW1 and PW2 may include an insulating material including an inorganic material and/or an organic material. For example, the first and second partition walls PW1 and PW2 may include at least one inorganic layer including various inorganic insulating materials including SiNₓ, SiOₓ, or the like. In other embodiments, the first and second partition walls PW1 and PW2 may include at least one organic layer including various organic insulating materials, a photoresist layer, and/or the like, or may be configured of an insulator of a single layer or multiple layers including organic/inorganic materials in combination. For example, a configuration material of the first and second partition walls PW1 and PW2 may be variously changed.

In an embodiment, the first and second partition walls PW1 and PW2 may function as a reflective member. As an example, the first and second partition walls PW1 and PW2 may function as a reflective member that guides the light emitted from each light emitting element LD in a desired direction together with the first and second electrodes ETL1 and ETL21 provided thereon to improve light efficiency of the pixel PXL.

The first and second electrodes ETL1 and ETL21 may be respectively disposed on the first and second partition walls PW1 and PW2. The first and second electrodes ETL1 and ETL21 may be disposed to be spaced apart from each other. The first and second electrodes ETL1 and ETL21 may be formed on a same layer.

As an embodiment, the first and second electrodes ETL1 and ETL21 or the like disposed on the first and second partition walls PW1 and PW2, respectively, may have shapes corresponding to shapes of each of the first and second partition walls PW1 and PW2. For example, each of the first and second electrodes ETL1 and ETL21 may have an inclined surface or a curved surface corresponding to the shapes of the first and second partition walls PW1 and PW2 and may protrude in the thickness direction of the first display device DV1.

Each of the first and second electrodes ETL1 and ETL21 may include at least one conductive material. For example, each of the first and second electrodes ETL1 and ETL21 may include a metal such as Ag, Mg, Al, Pt, Pd, Au, Ni, Nd, Ir, Cr, Ti, and an alloy thereof, a conductive oxide such as ITO, IZO, ZnO, and ITZO, and a conductive polymer such as PEDOT, but is not limited thereto.

Each of the first and second electrodes ETL1 and ETL21 may be configured as a single layer or a multi-layer. For example, each of the first and second electrodes ETL1 and ETL21 may include at least one reflective electrode layer. Each of the first and second electrodes ETL1 and ETL21 may selectively further include at least one of at least one transparent electrode layer disposed on and/or under the reflective electrode layer and at least one conductive capping layer covering an upper portion of the reflective electrode layer and/or the transparent electrode layer.

According to an embodiment, the reflective electrode layers of each of the first and second electrodes ETL1 and ETL21 may be formed of an electrode material having a uniform reflectance. As an example, the reflective electrode layer may include at least one of a metal such as Ag, Mg, Al, Pt, Pd, Au, Ni, Nd, Ir, Cr, and an alloy thereof, but is not limited thereto. For example, the reflective electrode layer may be formed of various reflective electrode materials. In case that each of the first and second electrodes ETL1 and ETL21 includes a reflective electrode layer, the light emitted from the ends of each of the light emitting elements LD, that is, one ends (or first ends) and the other ends (or second ends), may be allowed to be further progressed in a direction in which an image is displayed (for example, the third direction DR3, a front direction). For example, in case that the first and second electrodes ETL1 and ETL21 have the inclined surfaces or the curved surfaces corresponding to the shapes of the first and second partition walls PW1 and PW2 and are disposed to face the one ends and the other ends of each of the light emitting elements LD, the light emitted from the one ends and the other ends of each of the light emitting elements LD may be reflected by the first and second electrodes ETL1 and ETL21 and may be further progressed in the front direction (e.g., the third direction DR3 that is an upper direction of the base layer SUB1) of the first display device DV1. Accordingly, efficiency of the light emitted from the light emitting elements LD may be improved.

The transparent electrode layers of each of the first and second electrodes ETL1 and ETL21 may be formed of various transparent electrode materials. As an example, the transparent electrode layer may include ITO, IZO, or ITZO, but is not limited thereto. In an embodiment, each of the first and second electrodes ETL1 and ETL21 may be configured as a triple layer having a stack structure of ITO/Ag/ITO. As described above, in case that the first and second electrodes ETL1 and ETL21 are configured as at least two or more multiple layers, a voltage drop due to a signal delay (e.g., RC delay) may be minimized. Accordingly, a desired voltage may be effectively transferred to the light emitting elements LD.

In case that each of the first and second electrodes ETL1 and ETL21 includes the conductive capping layer covering the reflective electrode layer and/or the transparent electrode layer, the reflective electrode layer or the like of the first and second electrodes ETL1 and ETL21 may be prevented from being damaged due to a defect occurring in a manufacturing process or the like of the pixel PXL. However, the conductive capping layer may be selectively included in the first and second electrodes ETL1 and ETL21 and may be omitted according to an embodiment. The conductive capping layer may be regarded as a component of each of the first and second electrodes ETL1 and ETL21 or regarded as a separate component disposed on the first and second electrodes ETL1 and ETL21.

As an embodiment, the second electrodes ETL21, ETL22, and ETL23 may overlap the first connection pattern CE1 in at least a partial area thereof. The second electrodes ETL21, ETL22, and ETL23 may contact the first connection pattern CE1 through contact holes CH passing through the second protection layer 122.

The first insulating layer 131 may be disposed on an area of the first and second electrodes ETL1 and ETL21 in the first display area DA1. For example, the first insulating layer 131 may include an opening formed to cover an area of the first and second electrodes ETL1 and ETL21 and exposing another area of the first and second electrodes ETL1 and ETL21.

In an embodiment, the first insulating layer 131 may be formed to firstly cover the first and second electrodes ETL1 and ETL21 entirely. After the light emitting elements LD are supplied and aligned on the first insulating layer 131, the first insulating layer 131 may be partially opened to expose the first and second electrodes ETL1 and ETL21. As another example, the first insulating layer 131 may be patterned in a form of an individual pattern locally disposed under the light emitting elements LD after the supply and alignment of the light emitting elements LD are completed.

For example, the first insulating layer 131 may be interposed between the first and second electrodes ETL1 and ETL21 and the light emitting elements LD, and may expose at least one area of each of the first and second electrodes ETL1 and ETL21. After the first and second electrodes ETL1 and ETL21 are formed, the first insulating layer 131 may be formed to cover the first and second electrodes ETL1 and ETL21, to prevent damage of the first and second electrodes ETL1 and ETL21 or precipitation of metal. The first insulating layer 131 may stably support each light emitting element LD. According to an embodiment, the first insulating layer 131 may be omitted.

The light emitting elements LD may be supplied and aligned in an area of the first insulating layer 131. For example, the light emitting elements LD may be supplied through an inkjet method or the like, and the light emitting elements LD may be aligned between the first and second electrodes ETL1 and ETL21 by an alignment voltage (or alignment signal) applied to the first and second electrodes ETL1 and ETL21.

As an embodiment, a thickness of the first insulating layer 131 may be in a range of about 2,500 Å (angstrom) to about 3,500 Å.

A bank BNK may be disposed on the first insulating layer 131. For example, the bank BNK may be formed between other sub-pixels to surround each of the sub-pixels (SPX11 to SPX23 of FIG. 11), and may configure a pixel defining layer that partitions (or divides) the emission area.

According to an embodiment, the bank BNK may not be disposed between the unit pixels SSPX1 to SSPXk in the same sub-pixels SPX11 to SPX23, but is not limited thereto.

The second insulating layer 132 may be disposed on the light emitting elements LD, in particular, the light emitting elements LD aligned between the first and second electrodes ETL1 and ETL21, and may expose the one ends and the other ends of the light emitting elements LD. For example, the second insulating layer 132 may be partially disposed on only one area of the light emitting elements LD without covering the one ends and the other ends of the light emitting elements LD. The second insulating layer 132 may be formed in an independent pattern on each emission area, but is not limited thereto. As shown in FIGS. 21 and 22, in case that a separation space exists between the first insulating layer 131 and the light emitting elements LD before formation of the second insulating layer 132, the space may be filled by the second insulating layer 132. Accordingly, the light emitting elements LD may be more stably supported.

As an embodiment, a thickness of the second insulating layer 132 may be in a range of about 7,500 Å to about 8,500 Å.

The first and second contact electrodes CNE1 and CNE21 may be disposed on the first and second electrodes ETL1 and ETL21 and the one ends and the other ends of the light emitting elements LD.

In an embodiment, the first and second contact electrodes CNE1 and CNE21 may be disposed on different layers as shown in FIGS. 21 and 22.

The second contact electrode CNE21 may be disposed on the second electrodes ETL21, ETL22, and ETL23 to contact the second electrodes ETL21, ETL22, and ETL23. As an example, the second contact electrode CNE21 may be disposed to contact the second electrode ETL21 on an area of the second electrode ETL21 that is not covered by the first insulating layer 131. The second contact electrode CNE21 may be disposed on one ends of the light emitting elements LD adjacent to the second electrode ETL21 to contact the one ends of the light emitting elements LD. For example, the second contact electrode CNE21 may be disposed to cover the one ends of the light emitting elements LD and at least one area of the second electrode ETL21 corresponding thereto. Accordingly, the one end of the light emitting elements LD may be electrically connected to each second electrode ETL21.

A first bridge pattern BE1 and a second bridge pattern BE2 may be disposed on the same layer as the second contact electrode CNE21. The first bridge pattern BE1, the second bridge pattern BE2, and the second contact electrode CNE21 may be simultaneously formed by a same process.

The first bridge pattern BE1 may electrically connect adjacent antenna patterns ANTE to each other. The first bridge pattern BE1 may be disposed on the first insulating layer 131 and the bank BNK, and may be formed across an adjacent sub-pixels beyond the bank BNK.

The second bridge pattern BE2 may electrically connect adjacent touch electrode patterns TS. The second bridge pattern BE2 may be disposed on the first insulating layer 131 and the bank BNK, and may be formed across an adjacent sub-pixel beyond the bank BNK.

The third insulating layer 133 may be disposed on the first and second partition walls PW1 and PW2, the first and second electrodes ETL1 and ETL21, the light emitting elements LD, the second contact electrodes CNE21, the first and second bridge patterns BE1 and BE2, and the bank BNK to cover the first and second partition walls PW1 and PW2, the first and second electrodes ETL1 and ETL21, the light emitting elements LD, the second contact electrodes CNE21, the first and second bridge patterns BE1 and BE2, and the bank BNK.

As an embodiment, a thickness of the third insulating layer 133 may be in a range of about 2,500 Å (angstrom) to 3,500 Å. First contact holes CNT1 exposing at least a portion of the first bridge pattern BE1 and second contact holes CNT2 exposing at least a portion of the second bridge pattern BE2 may be formed in the third insulating layer 133.

According to an embodiment, each of the first to third insulating layers 131, 132, and 133 may be configured as a single layer or multiple layers, and may include at least one inorganic insulating material and/or organic insulating material. For example, each of the first to third insulating layers 131, 132, and 133 may include various types of organic/inorganic insulating materials, including SiNₓ, and a configuration material of each of the first to third insulating layers 131, 132, and 133 is not particularly limited thereto. The first to third insulating layers 131, 132, and 133 may include different insulating materials, or at least some of the first to third insulating layers 131, 132, and 133 may have a same insulating material.

The first contact electrode CNE1 may be disposed on the third insulating layer 133. As an example, the first contact electrode CNE1 may be disposed to contact the first electrode ETL1 on an area of the first electrode ETL1 that is not covered by the first insulating layer 131. The first contact electrode CNE1 may be disposed on the other ends of the light emitting elements LD adjacent to the first electrode ETL1 to contact the other ends of the light emitting elements LD. For example, the first contact electrode CNE1 may be disposed to cover the other end of the light emitting elements LD and at least one area of the first electrode ETL1 corresponding thereto. Accordingly, the other ends of the light emitting elements LD may be electrically connected to each first electrode ETL1.

The antenna pattern ANTE and the touch electrode pattern TS may be disposed on the same layer as the first contact electrode CNE1. The antenna pattern ANTE, the touch electrode pattern TS, and the first contact electrode CNE1 may be simultaneously formed by a same process.

As an embodiment, the first and second contact electrodes CNE1 and CNE21 may be formed of a transparent conductive material such as ITO, IZO, and ITZO so that the light emitted from the light emitting elements LD may pass therethrough. Similarly, the antenna pattern ANTE and the touch electrode pattern TS may be formed of a transparent conductive material such as ITO, IZO, and ITZO.

The antenna pattern ANTE may be in contact with the first bridge pattern BE1 through first contact holes CNT1, and the touch electrode pattern TS may be in contact with the second bridge pattern BE2 through second contact holes CNT2.

The encapsulation layer 141 including at least one inorganic layer and/or organic layer may be disposed on the antenna pattern ANTE, the touch electrode pattern TS, and the first contact electrode CNE1. The encapsulation layer 141 may be another insulating layer. The encapsulation layer 141 may correspond to the encapsulation layer TFE of FIG. 10. According to an embodiment, the encapsulation layer 141 may be omitted.

In the specification, elements disposed from the first and second partition walls PW1 and PW2 to the first contact electrode CNE1 are referred to as a light emitting element layer. For example, the light emitting element layer corresponds to layers including light emitting elements in the display substrate SUB DA.

An electromagnetic wave of the antenna pattern ANTE may be radiated to a front surface or a rear surface of the first display device DV1. For example, since another conductive material is not disposed on the antenna pattern ANTE, the first display device DV1 may perform communication by minimizing loss in about 5G frequency band (e.g., in a range of about 28 GHz to about 39 GHz frequency band).

A description of the antenna pattern ANTE of the first display device DV1 may be similarly applied to the second to fourth display devices DV2 to DV4.

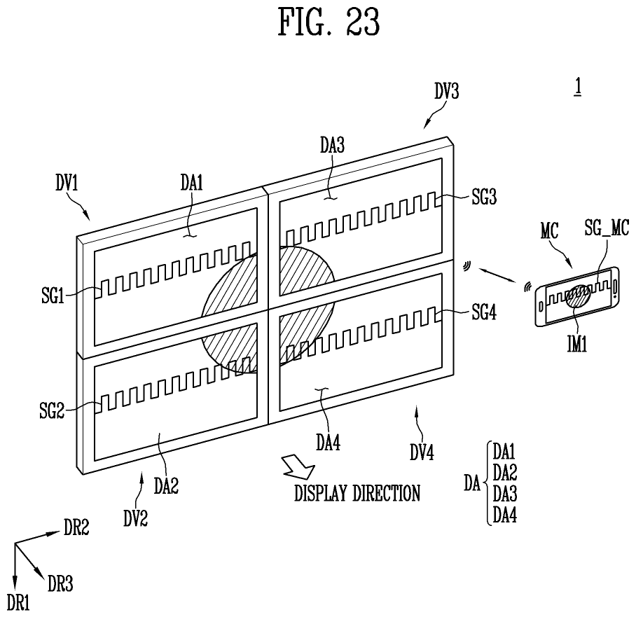

FIG. 23 is a conceptual diagram illustrating a driving signal of each display device of a video wall display system according to an embodiment of the disclosure.

Referring to FIG. 23, each of the display devices DV1 to DV4 of the video wall display system 1 may include the above-described antenna pattern ANTE, and communication of the above-described 5G frequency band is possible with a minimum loss rate.

Accordingly, a wireless signal SG_MC may be provided from a control part MC to each of the display devices DV1 to DV4, and a delay time (latency) between signals SG1 to SG4 received by the display devices DV1 to DV4 may be extremely short, or may not occur practically.

Accordingly, a user may watch each of the display devices DV1 to DV4 of the video wall display system 1, and feel first to fourth sub-images IM21 to IM24 as an image.

A video wall display system according to another embodiment is described below. Hereinafter, a description of the same constituent elements in FIGS. 1 to 23 and the drawings is omitted, and the same or similar reference numerals are used.

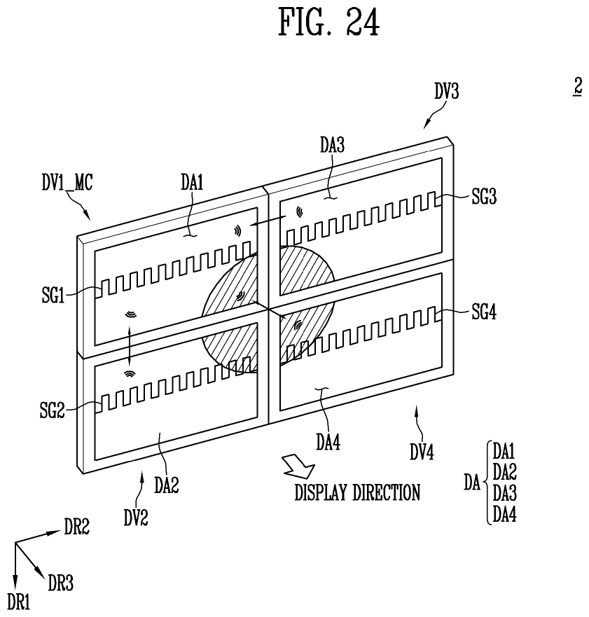

FIG. 24 is a schematic perspective view of a video wall display system according to another embodiment of the disclosure.

Referring to FIG. 24, the video wall display system 2 according to the embodiment is different from the video wall display system 1 of FIG. 1 in that a function of a control part MC is merged to a first display device DV1.

The first display device DV1_MC may have both of the function of the first display device DV1 and the function of the control part MC described above with reference to FIGS. 1 and 2. Since the description of FIGS. 3 to 23 may be similarly applied to a description of the first display device DV1_MC and the second to fourth display devices DV2 to DV4, detailed description of the same elements is omitted.

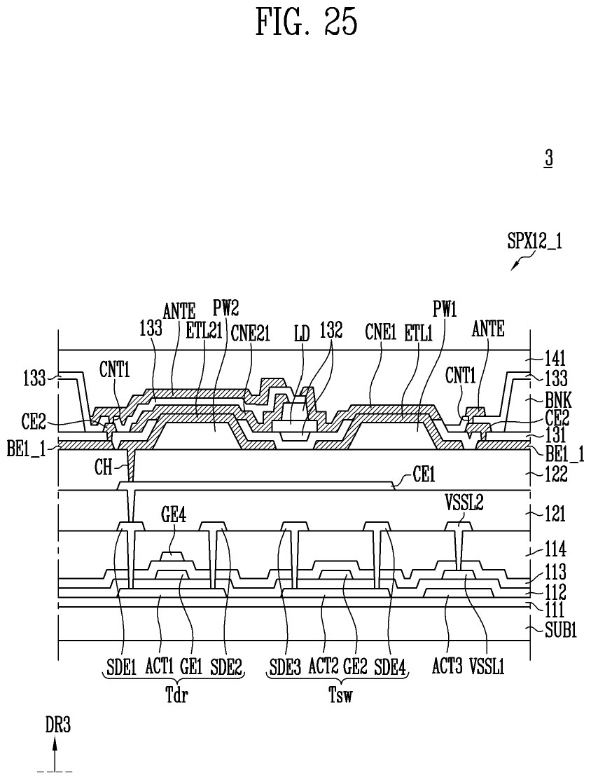

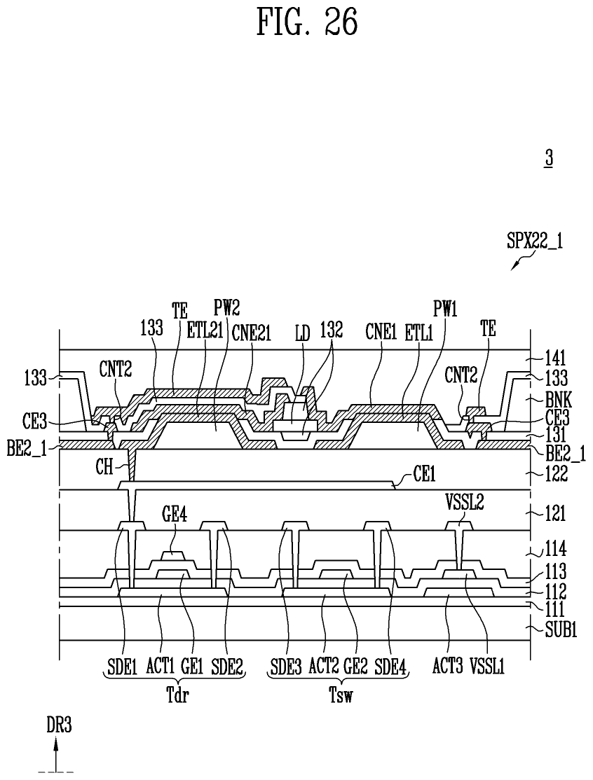

FIGS. 25 and 26 are schematic cross-sectional views of a display substrate to an encapsulation layer of a first display device of a video wall display system according to still another embodiment of the disclosure. FIGS. 25 and 26 correspond to modified examples of FIGS. 21 and 22, respectively.

Referring to FIGS. 25 and 26, the first display device of the video wall display system 3 according to the embodiment is different from the embodiment of FIGS. 21 and 22 in that a first bridge pattern BE1_1 and a second bridge pattern BE2_1 are formed on the same layer as a first electrode ETL1 and a second electrodes ETL21, in each sub-pixel (for example, a second sub-pixel SPX12_1, a fifth sub-pixel SPX22_1, and the like).

An antenna pattern ANTE may contact a second connection pattern CE2 formed on the same layer as a second contact electrode CNE21 through a first contact hole CNT1, and a second connection pattern CE2 may contact the first bridge pattern BE1_1. The first bridge pattern BE1_1 may pass under a bank BNK and may be electrically connected to the antenna pattern ANTE of an adjacent sub-pixel.

A touch electrode pattern TS (e.g., the driving electrode TE) may contact a third connection pattern CE3 formed on the same layer as the second contact electrode CNE21 through a second contact hole CNT2, and the third connection pattern CE3 may contact the second bridge pattern BE2_1. The second bridge pattern BE2_1 may pass under the bank BNK and may be electrically connected to the touch electrode pattern TS of the adjacent sub-pixel.

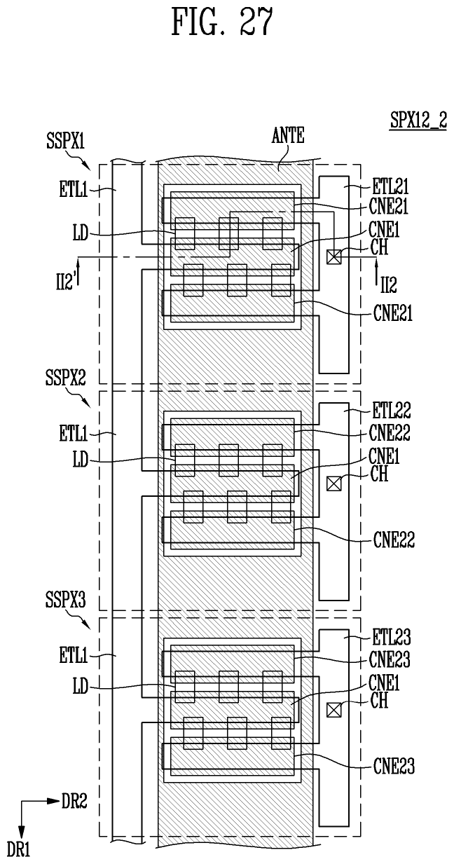

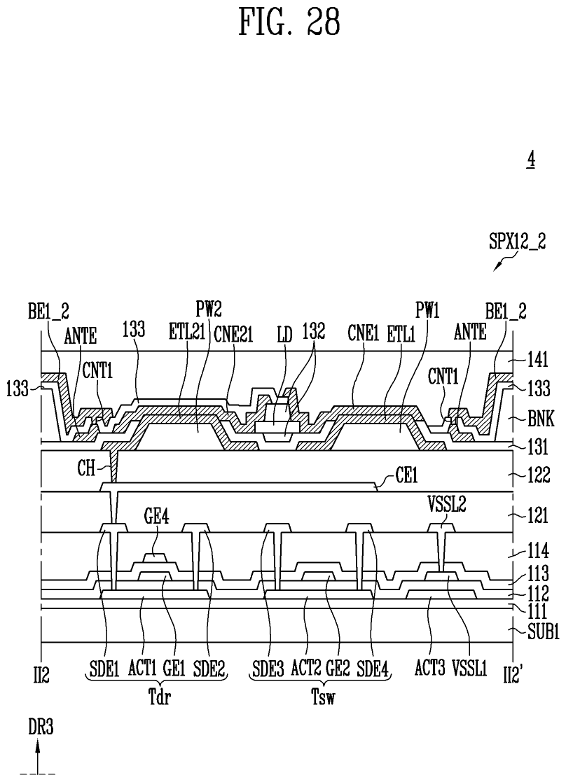

FIG. 27 is a plan layout diagram schematically illustrating a disposition of a sub-pixel included in a first display device of a video wall display system according to still another embodiment of the disclosure. FIG. 28 is a schematic cross-sectional view of the display substrate to the encapsulation layer corresponding to line II2-II2′ of FIG. 27 in the first display device. Hereinafter, since a shape of the touch electrode pattern included in the fifth sub-pixel is the same as a shape of the antenna pattern ANTE included in the second sub-pixel SPX12_2, and only functions are different, detailed description of the same elements is omitted.

Referring to FIGS. 27 and 28, the first display device of the video wall display system 4 according to the embodiment is different from the embodiment of FIGS. 19 and 21 in that an antenna pattern ANTE and a touch electrode pattern are formed on the same layer as a second contact electrode CNE21, CNE22 and CNE23.

The antenna pattern ANTE and the touch electrode pattern may be formed on the same layer as the second contact electrode CNE21. The antenna pattern ANTE and the touch electrode pattern may not overlap the first contact electrode CNE1 and the second contact electrode CNE21, respectively, and may be electrically separated from each other in a plan view. The first contact electrode CNE1 and the second contact electrode CNE21 may be surrounded by the antenna pattern ANTE and the touch electrode pattern in a plan view.

A first bridge pattern BE1_2 may be formed on the same layer as the first contact electrode CNE1. The first bridge pattern BE1_2 may be electrically connected to the antenna pattern ANTE through a first contact hole CNT1. The first bridge pattern BE1_2 may electrically connect the antenna patterns ANTE between adjacent pixels beyond the bank BNK.

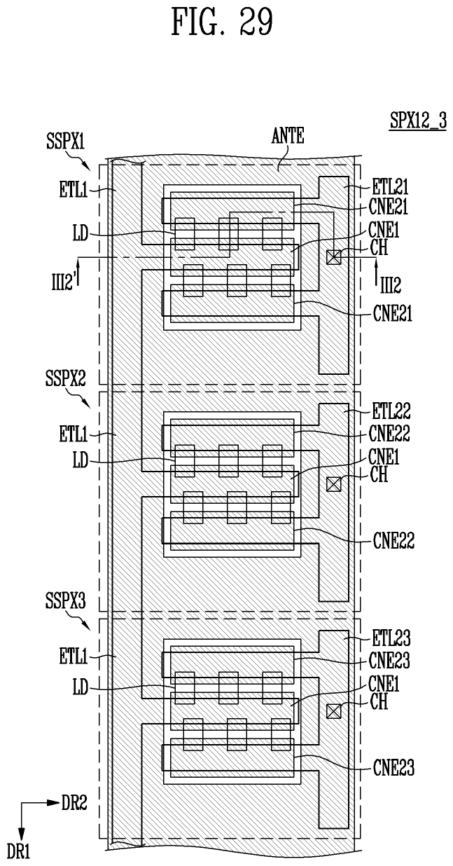

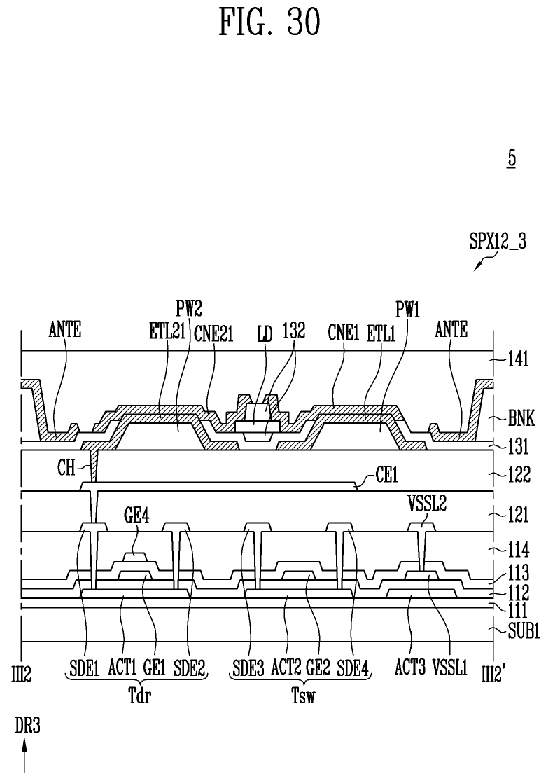

FIG. 29 is a plan layout diagram schematically illustrating a disposition of a sub-pixel (for example, a second sub-pixel SPX12_3) included in a first display device of a video wall display system according to still another embodiment of the disclosure. FIG. 30 is a schematic cross-sectional view of the display substrate to the encapsulation layer corresponding to line III2-III2′ of FIG. 29 in the first display device.

Referring to FIGS. 29 and 30, the first display device of the video wall display system 5 according to the embodiment is different from the embodiment of FIGS. 19 and 21 in that all of an antenna pattern ANTE, a touch electrode pattern, a first contact electrode CNE1, and a second contact electrode CNE21 are formed on a same layer.

The antenna pattern ANTE, the touch electrode pattern, the first contact electrode CNE1, and the second contact electrode CNE21 may be simultaneously formed by a same process. The antenna pattern ANTE, the touch electrode pattern, the first contact electrode CNE1, and the second contact electrode CNE21 may be electrically separated from each other. The first contact electrode CNE1 and the second contact electrode CNE21 may be surrounded by the antenna pattern ANTE and the touch electrode pattern in a plan view.

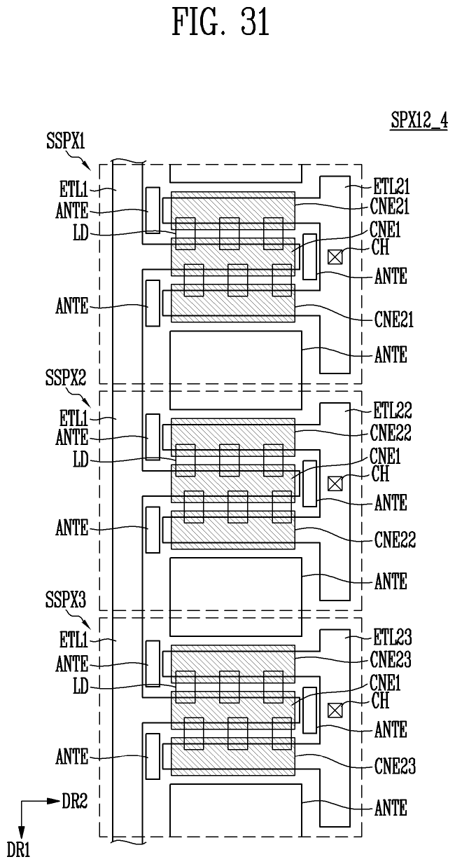

FIG. 31 is a plan layout diagram schematically illustrating a disposition of a sub-pixel (for example, a second sub-pixel SPX12_4) included in a first display device of a video wall display system according to still another embodiment of the disclosure.

Referring to FIG. 31, the first display device of the video wall display system according to the embodiment is different from the embodiment of FIG. 19 in that an antenna pattern ANTE and a touch electrode pattern are formed on the same layer as a first electrode ETL1 and a second electrode ETL21, ETL22, and ETL23.

The antenna pattern ANTE and the touch electrode pattern may be formed simultaneously with the first electrode ETL1 and the second electrodes ETL21, ETL22, and ETL23 by the same process as the first electrode ETL1 and the second electrodes ETL21, ETL22, and ETL23. The antenna pattern ANTE and the touch electrode pattern may be electrically separated from the first electrode ETL1 and the second electrodes ETL21, ETL22, and ETL23.

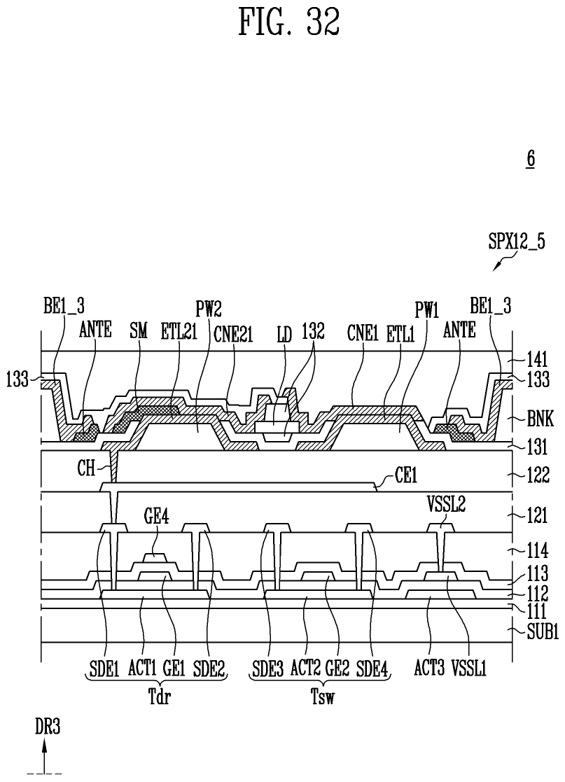

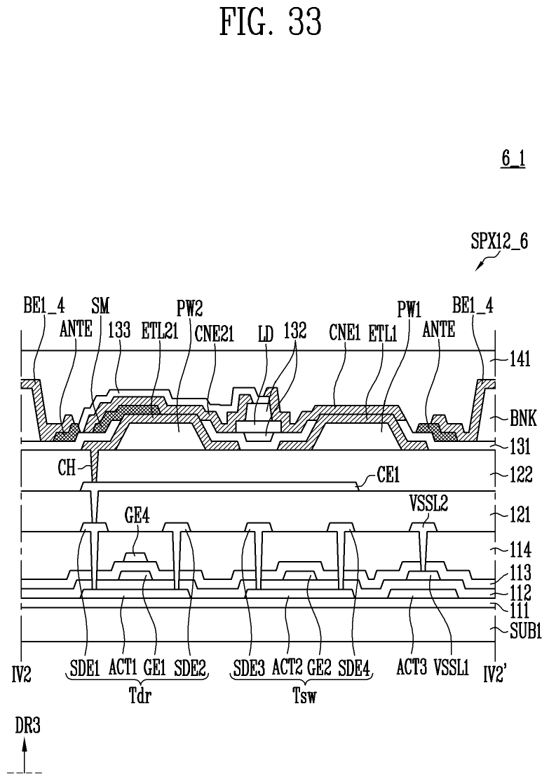

FIG. 32 is a schematic cross-sectional view of a display substrate to an encapsulation layer in a first display device of a video wall display system according to still another embodiment of the disclosure. FIG. 33 is a modified example of FIG. 32.

Referring to FIG. 32, the first display device of the video wall display system 6 according to the embodiment is different from the embodiment of FIGS. 19 and 21 in that the first display device of the video wall display system 6 further includes a shielding electrode SM, and an antenna pattern ANTE and a touch electrode pattern is formed on the same layer as a shielding electrode SM.

In each sub-pixel (for example, a second sub-pixel SPX12_5), a shielding electrode SM may be formed on the first insulating layer 131, the first electrode ETL1, and the second electrode ETL21 to surround an area where each of the light emitting elements LD is aligned, and after the light emitting elements LD are aligned, the shielding electrode SM may be patterned to form the shielding electrode SM and the antenna pattern ANTE.

As an embodiment, the shielding electrode SM may include an external light absorbing material formed of at least one of Cr/CrOₓ, CrOₓ, MoOₓ, carbon pigment, and RGB pigment.

As an embodiment, the shielding electrode SM may be disposed (e.g., directly disposed) under a second contact electrode CNE21. The shielding electrode SM may be disposed between the second electrode ETL21 and the second contact electrode CNE21.

Although not clearly shown, the antenna pattern ANTE may be formed to surround the first contact electrode CNE1 and the second contact electrode CNE21.

As an embodiment, a bridge pattern BE1_3 may be formed on the same layer as the second contact electrode CNE21. The bridge pattern BE1 3 may be directly patterned on the antenna pattern ANTE to cross the bank BNK. The bridge pattern BE1_3 may electrically connect the antenna patterns ANTE respectively disposed in adjacent sub-pixels.

Referring to FIG. 33, in a sub-pixel (for example, a second sub-pixel SPX12_6) of the first display device in a video wall display system 6_1 according to the embodiment, a bridge pattern BE1_4 may be formed on the same layer as a second contact electrode CNE21. The bridge pattern BE1_4 may be directly patterned on the antenna pattern ANTE to cross (or intersect) the bank BNK. The bridge pattern BE1_4 may electrically connect the antenna patterns ANTE respectively disposed in adjacent sub-pixels.

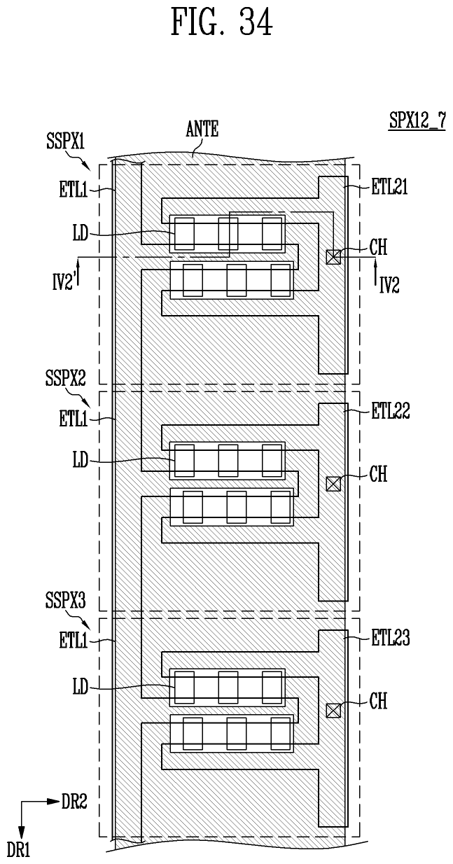

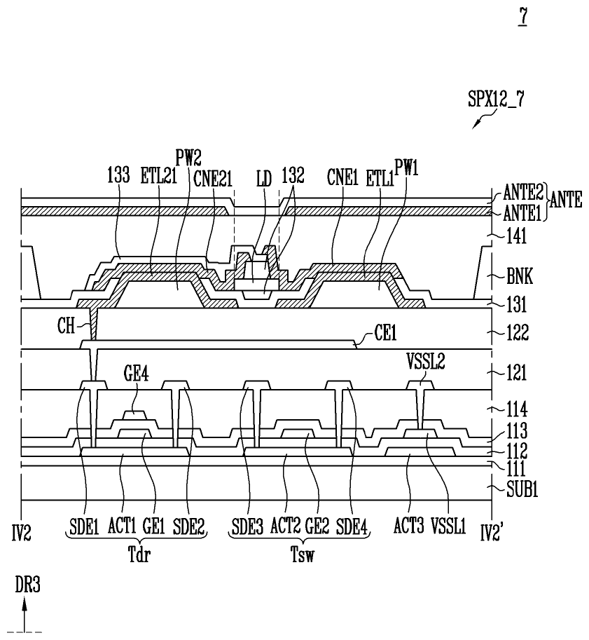

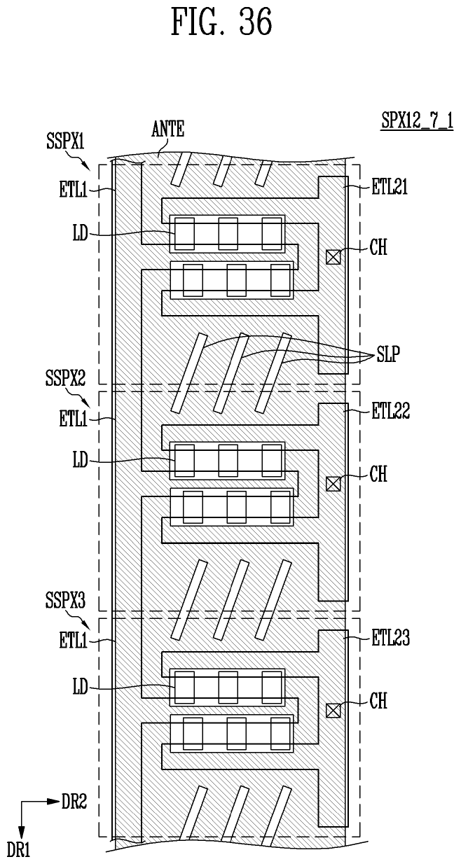

FIG. 34 is a plan layout diagram schematically illustrating a disposition of a sub-pixel (for example, a second sub-pixel SPX12_7) included in a first display device of a video wall display system according to still another embodiment of the disclosure. FIG. 35 is a schematic cross-sectional view of the display substrate to the encapsulation layer corresponding to line IV2-IV2′ of FIG. 34 in the first display device. FIG. 36 is a modified example of FIG. 34.

Referring to FIGS. 34 and 35, the first display device of the video wall display system 7 according to the embodiment is different from the embodiment of FIGS. 19 and 21 in that a conductive layer on which an antenna pattern ANTE 15 formed is separated disposed on an encapsulation layer 141.

As an embodiment, the antenna pattern ANTE may be disposed on the encapsulation layer 141 and may be formed of multiple layers. For example, the antenna pattern ANTE may include a first antenna pattern layer ANTE1 and a second antenna pattern layer ANTE2 that are sequentially stacked.

The first antenna pattern layer ANIE1 may not overlap an area where a light emitting element LD is aligned. As an embodiment, the first antenna pattern layer ANIE1 may include a metal capable of reflecting external light or a transparent electrode. As an example, the first antenna pattern layer ANTE1 may include chromium (Cr), titanium (Ti), aluminum (Al), gold (Au), nickel (Ni), or an oxide or an alloy thereof capable of reflecting external light, or may include a transparent electrode material such as indium tin oxide (ITO), indium zinc oxide (IZO), zinc oxide (ZnO), and indium tin zinc oxide (ITZO).

The second antenna pattern layer ANTE2 may include a transparent electrode material described above as an example in the first antenna pattern layer ANTE1. The second antenna pattern layer ANTE2 may include a function of improving visibility due to reflection of external light.

Referring to FIG. 36, in a sub-pixel (for example, a second sub-pixel SPX12_7_1), the antenna pattern ANTE may include a slit pattern SLP. The slit pattern SLP may include a function of improving visibility and reducing noise.

In a process in which the antenna pattern ANTE is formed, the antenna pattern ANTE may be removed from a portion where the slit pattern SLP is to be formed.

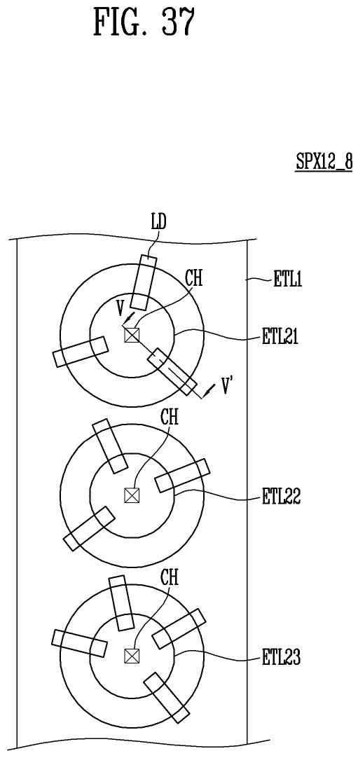

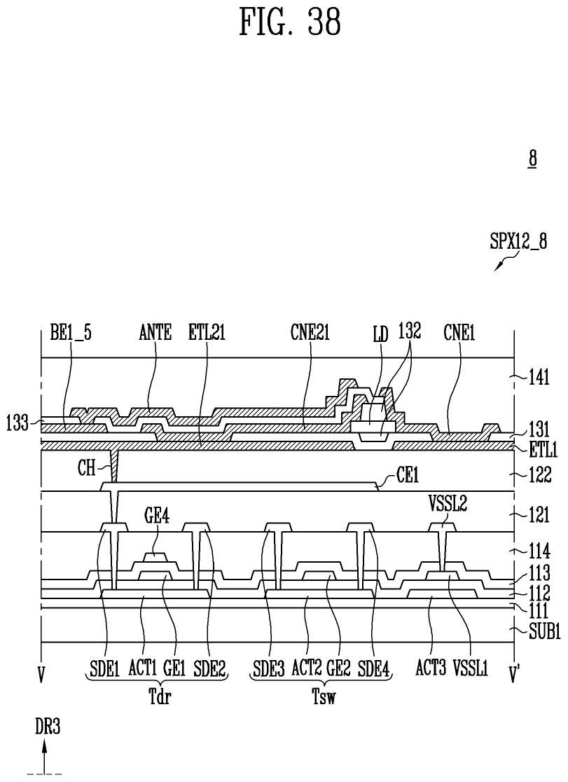

FIG. 37 is a plan layout diagram schematically illustrating a disposition of a sub-pixel (for example, a second sub-pixel SPX12_8), included in a first display device of a video wall display system according to still another embodiment of the disclosure. FIG. 38 is a schematic cross-sectional view of the display substrate to the encapsulation layer corresponding to line V-V′ of FIG. 37 in the first display device.

Referring to FIGS. 37 and 38, in the first display device of the video wall display system 8 according to the embodiment, an area where a light emitting element LD is arranged may have a circular shape, compared to the embodiment of FIGS. 19 and 21.

A shape between a first electrode ETL1 and a second electrode ETL21 may be circular. The second electrode ETL21 may have a circular shape, and the second electrode ETL21 may be surrounded by the first electrode ETL1. The light emitting elements LD may be radially disposed with respect to the second electrode ETL21. Accordingly, light emitted from the light emitting elements LD may not be focused in a specific direction, and the first display device having a uniform light output distribution may be provided. In addition, a bridge pattern BE1_5 may be formed on the same layer as the second contact electrodes CNE21.

Although the partition wall is omitted in the drawing, the disclosure is not limited thereto.

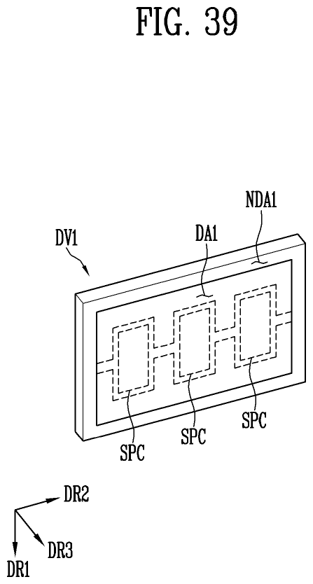

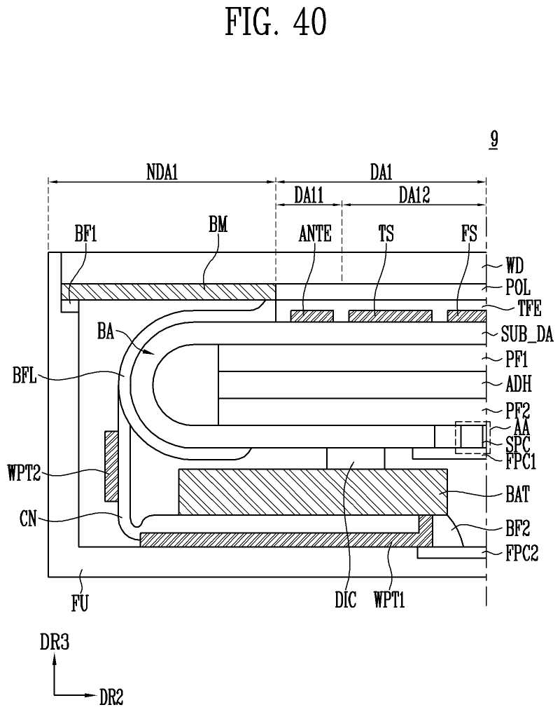

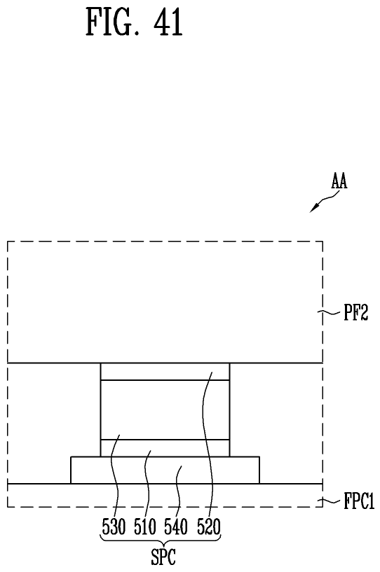

FIG. 39 is a schematic perspective view of a first display device of a video wall display system according to still another embodiment of the disclosure. FIG. 40 is a schematic cross-sectional view of the first display device shown in FIG. 39. FIG. 41 is a schematic enlarged view of area AA of FIG. 40.

Referring to FIGS. 39 to 41, the first display device DV1 of the video wall display system 9 according to the embodiment is different from the embodiment of FIGS. 1 and 10 in that the first display device DV1 of the video wall display system 9 further includes a speaker member SPC.

The speaker member SPC may be disposed adjacent to an area positioned in a relatively lower portion in a display substrate SUB_DA. In the embodiment, the speaker member SPC is disposed between a second protection film PF2 and a first flexible circuit board FPC1. In another embodiment, the speaker member SPC may be mounted (e.g., directly mounted) on a rear surface of the display substrate SUB_DA.

The speaker member SPC may be positioned adjacent to a lower portion of the display substrate SUB_DA to prevent being viewed from an upper portion of the display substrate SUB_DA.

The speaker member SPC may generate a vibration in response to a first vibration signal to output a first vibration. The speaker member SPC may vibrate the display substrate SUB_DA through the first vibration to output the first sound. Thus, the speaker member SPC may vibrate by a vibration layer 530 deformed in response to the first vibration signal. As another example, a current according to the first vibration signal may flow through a coil surrounding a magnet of the speaker member SPC to generate electromagnetic force, and thus the speaker member SPC may vibrate by the electromagnetic force. Hereinafter, the disclosure is described based on the speaker member SPC generating the sound by vibration of the vibration layer 530.

The speaker member SPC may include a first speaker electrode 510, a second speaker electrode 520, the vibration layer 530, and a speaker substrate 540.

The first speaker electrode 510 may be disposed on a first surface of the speaker substrate 540, the vibration layer 530 may be disposed on the first speaker electrode 510, and the second speaker electrode 520 may be disposed on the vibration layer 530.

The first speaker electrode 510 and the second speaker electrode 520 may be formed of a conductive material. For example, the conductive material of the first speaker electrode 510 and the second speaker electrode 520 may be a transparent conductive material such as indium tin oxide (ITO) and indium zinc oxide (IZO), an opaque metal material, a conductive polymer, carbon nanotube (CNT), or the like.

The vibration layer 530 may be a piezo actuator deformed according to a difference between a voltage applied to the first speaker electrode 510 and a voltage applied to the second speaker electrode 520. The vibration layer 530 may be at least one piezoelectric material such as a poly vinylidene fluoride (PVDF) film, a lead zirconate titanate ceramic (PZT), and an electro active polymer.

The vibration layer 530 may contract, relax, or expand according to a difference between a first driving voltage applied to the first speaker electrode 510 and a second driving voltage applied to the second speaker electrode 520. In case that the first driving voltage applied to the first speaker electrode 510 and the second driving voltage applied to the second speaker electrode 520 are alternately repeated with a positive polarity and a negative polarity, the vibration layer 530 may repeat contraction and relaxation. Accordingly, the speaker member SPC may vibrate, and thus since the display substrate SUB_DA vibrates up and down, the first sound may be output.

As an embodiment, the speaker member SPC may reproduce a frequency band of a middle register region and a high-pitched region. For example, the speaker member SPC may reproduce the first sound having a frequency in a range of about 4 kHz to about 20 kHz. For example, the speaker member SPC may be a tweeter.

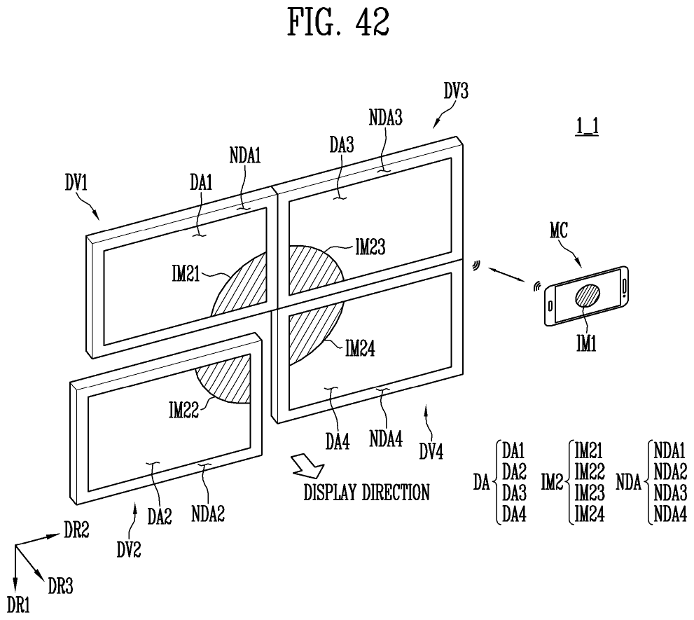

FIG. 42 is a modified example of FIG. 1.

Referring to FIG. 42, a disposition shape of the first to fourth display devices DV1 to DV4 in a video wall display system 1_1 according to the embodiment may be irregular.

Since the first to fourth display devices DV1 to DV4 may be connected to each other by the network communication part 270 (refer to FIG. 2) through a wireless network, the first to fourth display devices DV1 to DV4 may be freely disposed.

Although the embodiments of the disclosure have been described with reference to the accompanying drawings, those skilled in the art will understand that the embodiments may be implemented in other specific forms without changing the technical spirit and essential features of the disclosure. Therefore, it should be understood that the embodiments described above are illustrative and are not restrictive in all aspects.

What is claimed is:

1. A display device comprising:
a pixel circuit layer including a plurality of transistors;
a first electrode and a second electrode disposed on a same layer on the pixel circuit layer;
a light emitting element disposed between the first electrode and the second electrode; and
an antenna pattern disposed on the light emitting element.

2. The display device according to claim 1, further comprising:
a first contact electrode electrically connecting an end of the light emitting element and the first electrode.

3. The display device according to claim 2, wherein the antenna pattern and the first contact electrode are disposed on a same layer.

4. The display device according to claim 3, wherein the antenna pattern and the first contact electrode are electrically separated from each other.

5. The display device according to claim 3, further comprising:
a second contact electrode electrically connecting another end of the light emitting element and the second electrode.

6. The display device according to claim 5, wherein the first contact electrode is disposed on the second contact electrode.

7. The display device according to claim 5, further comprising:
an insulating layer disposed between the antenna pattern and the second contact electrode, wherein
the antenna pattern overlaps the second contact electrode in a plan view.

8. The display device according to claim 7, further comprising:
a first bridge pattern, wherein
the first bridge pattern and the second contact electrode are disposed on a same layer, and
the antenna pattern is electrically connected to the first bridge pattern through a first contact hole in the insulating layer.

9. The display device according to claim 5, wherein
the first contact electrode, the second contact electrode, and the antenna pattern are disposed on a same layer, and
the first contact electrode, the second contact electrode, and the antenna pattern are electrically separated from each other.

10. The display device according to claim 1, further comprising:
a touch electrode pattern,
wherein the touch electrode pattern and the antenna pattern are disposed on a same layer.

11. The display device according to claim 10, further comprising:
a first contact electrode, wherein
the first contact electrode, the antenna pattern, and the touch electrode pattern are disposed on a same layer, and
the first contact electrode electrically connects an end of the light emitting element and the first electrode.

12. The display device according to claim 1, wherein a transmit/receive frequency of the antenna pattern is in a range of about 28 GHz to about 39 GHz.

13. The display device according to claim 1, wherein the antenna pattern includes a transparent conductive material.

14. The display device according to claim 1, further comprising:
a first contact electrode electrically connecting an end of the light emitting element and the first electrode; and
a second contact electrode electrically connecting another end of the light emitting element and the second electrode, wherein
the first contact electrode is disposed on the second contact electrode, and
the antenna pattern is disposed under the second contact electrode.

15. The display device according to claim 1, further comprising:
a first contact electrode electrically connecting an end of the light emitting element and the first electrode; and
a second contact electrode electrically connecting another end of the light emitting element and the second electrode,
wherein the antenna pattern is disposed on the first contact electrode and the second contact electrode.

16. The display device according to claim 15, further comprising:
an encapsulation layer disposed on the first contact electrode and the second contact electrode, wherein
the antenna pattern is disposed on the encapsulation layer, and
the encapsulation layer includes at least one inorganic layer and an organic layer.

17. A video wall display system including a plurality of display devices,
each of the plurality of display devices comprising:
a display substrate; and
an antenna pattern disposed on the display substrate,
wherein the display substrate comprises:
a pixel circuit layer including a plurality of transistors;
a first electrode and a second electrode disposed on a same layer on the pixel circuit layer; and
a light emitting element disposed between the first electrode and the second electrode.

18. The video wall display system according to claim 17, wherein the plurality of display devices are electrically connected to each other through a wireless network.

19. The video wall display system according to claim 17, wherein the display substrate includes a bent area.

20. The video wall display system according to claim 17, further comprising:
a wireless power transfer antenna disposed under the display substrate.

21. The video wall display system according to claim 17, further comprising:
a speaker module disposed under the display substrate.

22. The video wall display system according to claim 21, wherein the speaker module includes:
a first speaker electrode;
a second speaker electrode; and
a vibration layer disposed between the first speaker electrode and the second speaker electrode.

23. The video wall display system according to claim 22, wherein the vibration layer includes at least one of poly vinylidene fluoride (PVDF), lead zirconate titanate ceramic (PZT), and electro active polymer.

24. A video wall display system including a plurality of display devices,
each of the plurality of display devices comprising:
a display substrate including:
a plurality of transistors, and
a plurality of light emitting elements;
an antenna pattern disposed on the display substrate; and
a network communication part transmitting and receiving a wireless signal to and from other display devices in the video wall display system through the antenna pattern.

25. The video wall display system according to claim 24, wherein each of the plurality of light emitting elements has a diameter and a length ranging from several hundred nanometer scale to several micrometer scale.

26. The video wall display system according to claim 24, further comprising:
a control part electrically connected to at least one of the plurality of display devices through a wireless network,
wherein the control part receives a user's instruction.
